(19) United States
(12) Patent Application Publication
(10) Pub. No.: US 2025/0275281 A1
(43) Pub. Date: Aug. 28, 2025

(54) PHOTOELECTRIC CONVERSION APPARATUS, PHOTOELECTRIC CONVERSION SYSTEM, MOVING BODY, AND EQUIPMENT

(71) Applicant: CANON KABUSHIKI KAISHA, Tokyo (JP)

(72) Inventors: TAIKAN KANOU, Kanagawa (JP); KAZUHIRO MORIMOTO, Kanagawa (JP); DAIKI SHIRAHIGE, Kanagawa (JP); HIROSHI SEKINE, Kanagawa (JP)

(21) Appl. No.: 19/208,094

(22) Filed: May 14, 2025

Related U.S. Application Data
(63) Continuation of application No. PCT/JP2023/042138, filed on Nov. 24, 2023.

(30) Foreign Application Priority Data
Nov. 30, 2022 (JP) 2022-192483
Sep. 28, 2023 (JP) 2023-168617

(51) Int. Cl. H10F 39/00; H10F 30/225; H10F 39/18

(52) U.S. Cl. CPC H10F 39/807; H10F 30/225; H10F 39/18; H10F 39/8063; H10F 39/809; H10F 39/811

(57) ABSTRACT

A photoelectric conversion apparatus realizes enhancement of characteristics of an avalanche photodiode. The photoelectric conversion apparatus includes an avalanche photodiode, and a semiconductor layer having a first and a second surfaces. The avalanche photodiode includes a first semiconductor region, a second semiconductor region that exists at a position closer to the second surface than the first semiconductor region, a third semiconductor region provided at a predetermined depth position of the semiconductor layer, a region to which a second voltage is applied, a fourth semiconductor region provided between the region and the third semiconductor region, and a dielectric member that is positioned in a portion overlapping at least the fourth semiconductor region in a planar view with respect to the second surface, and a portion extending from at least the second surface to an inside of the semiconductor layer, the portion being provided at the predetermined depth position.

### CROSS-REFERENCE TO RELATED APPLICATIONS

This application is a Continuation of International Patent Application No. PCT/JP2023/042138, filed Nov. 24, 2023, which claims the benefit of Japanese Patent Applications No. 2022-192483, filed Nov. 30, 2022, and No. 2023-168617, filed Sep. 28, 2023, all of which are hereby incorporated by reference herein in their entirety.

### BACKGROUND OF THE INVENTION

### Field of the Invention

The present invention relates to a photoelectric conversion apparatus, a photoelectric conversion system, a moving body and equipment.

### Background Art

A photoelectric conversion apparatus that uses an avalanche photodiode involving avalanche multiplication has recently been proposed.

PTL-1 discusses a configuration including a plurality of pixels each including an avalanche photodiode. In a region between the plurality of pixels, an isolation region including a dielectric member is formed.

### CITATION LIST

### Patent Literature

PTL 1: Japanese Patent Application Laid-Open No. 2022-55214

The isolation region including the dielectric member discussed in PTL-1 reduces a cross talk that occurs between the plurality of pixels, and the consideration on enhancement of characteristics of the avalanche photodiode is not enough.

### SUMMARY OF THE INVENTION

According to a technique of the present disclosure, a photoelectric conversion apparatus includes an avalanche photodiode configured to perform an avalanche multiplication operation with a first voltage and a second voltage that are applied, and a semiconductor layer having a first surface on which light is incident, and a second surface facing the first surface. The avalanche photodiode includes a first semiconductor region of a first conductivity type that is provided at a first depth from the first surface in the semiconductor layer, a second semiconductor region of a second conductivity type that exists at a position closer to the second surface than the first semiconductor region, a third semiconductor region of the first conductivity type that exists at a position closer to the second surface than the second semiconductor region, is applied with the first voltage, and is provided at a predetermined depth position of the semiconductor layer, a region to which the second voltage is applied, a fourth semiconductor region of the first conductivity type that is provided between the region and the third semiconductor region, and a dielectric member that is positioned in a portion overlapping at least the fourth semiconductor region in a planar view with respect to the second surface, and includes a portion extending from at least the second surface to an inside of the semiconductor layer. The portion is provided at the predetermined depth position.

According to another technique of the present disclosure, a photoelectric conversion apparatus includes a photoelectric conversion apparatus includes a plurality of avalanche photodiodes each performing an avalanche multiplication operation with a first voltage and a second voltage that are applied, and a semiconductor layer having a first surface on which light is incident, and a second surface facing the first surface. Each of the plurality of avalanche photodiodes includes a first semiconductor region of a first conductivity type that is provided at a first depth from the first surface in the semiconductor layer, a second semiconductor region of a second conductivity type that exists at a position closer to the second surface than the first semiconductor region, a third semiconductor region of the first conductivity type that exists at a position closer to the second surface than the second semiconductor region, and is provided at a predetermined depth position of the semiconductor layer, to which the first voltage is applied, a region to which the second voltage is applied, and a dielectric member, wherein an isolation region for isolating the plurality of avalanche diodes is provided. The dielectric member is positioned between the isolation region and the third semiconductor region in a planar view with respect to the second surface, and includes a portion extending from at least the second surface over the predetermined depth position.

Further features of the present invention will become apparent from the following description of exemplary embodiments with reference to the attached drawings.

### BRIEF DESCRIPTION OF THE DRAWINGS

FIG. 1 is an overall view of a photoelectric conversion apparatus.

FIG. 2 is an overall view of a sensor substrate.

FIG. 3 is an overall view of a circuit substrate.

FIG. 4 is a diagram illustrating a pixel circuit.

FIG. 5A is a diagram illustrating the pixel circuit.

FIG. 5B is a diagram illustrating a drive of the pixel circuit.

FIG. 5C is diagram illustrating a drive of the pixel circuit.

FIG. 6 is a cross-sectional view of a photoelectric conversion apparatus (first exemplary embodiment)

FIG. 7 is a cross-sectional view of a photoelectric conversion apparatus (first exemplary embodiment)

FIG. 8 is a plan view of a photoelectric conversion apparatus (first exemplary embodiment)

FIG. 9 is a plan view of a photoelectric conversion apparatus (first exemplary embodiment)

FIG. 10A is a manufacturing process diagram of a photoelectric conversion apparatus (first exemplary embodiment)

FIG. 10B is a manufacturing process diagram of a photoelectric conversion apparatus (first exemplary embodiment)

FIG. 10C is a manufacturing process diagram of a photoelectric conversion apparatus (first exemplary embodiment)

FIG. 11A is a manufacturing process diagram of a photoelectric conversion apparatus (first exemplary embodiment)

FIG. 11B is a manufacturing process diagram of a photoelectric conversion apparatus (first exemplary embodiment)

FIG. 11C is a manufacturing process diagram of a photoelectric conversion apparatus (first exemplary embodiment)

FIG. 12 is a cross-sectional view of a photoelectric conversion apparatus (second exemplary embodiment)

FIG. 13 is a plan view of a photoelectric conversion apparatus (second exemplary embodiment)

FIG. 14 is a cross-sectional view of a photoelectric conversion apparatus (third exemplary embodiment)

FIG. 15 is a plan view of a photoelectric conversion apparatus (third exemplary embodiment)

FIG. 16 is a cross-sectional view of a photoelectric conversion apparatus (fourth exemplary embodiment)

FIG. 17 is a plan view of a photoelectric conversion apparatus (fourth exemplary embodiment)

FIG. 18 is a plan view of a photoelectric conversion apparatus (fifth exemplary embodiment)

FIG. 19 is a plan view of a photoelectric conversion apparatus (fifth exemplary embodiment)

FIG. 20 is a cross-sectional view of a photoelectric conversion apparatus (sixth exemplary embodiment)

FIG. 21 is a cross-sectional view of a photoelectric conversion apparatus (seventh exemplary embodiment)

FIG. 22 is a plan view of a photoelectric conversion apparatus (seventh exemplary embodiment)

FIG. 23 is a cross-sectional view of a photoelectric conversion apparatus (seventh exemplary embodiment)

FIG. 24 is a plan view of a photoelectric conversion apparatus (seventh exemplary embodiment)

FIG. 25 is a plan view of a photoelectric conversion apparatus (seventh exemplary embodiment)

FIG. 26 is a cross-sectional view of a photoelectric conversion apparatus (eighth exemplary embodiment)

FIG. 27 is a plan view of a photoelectric conversion apparatus (eighth exemplary embodiment)

FIG. 28 is a cross-sectional view of a photoelectric conversion apparatus (eighth exemplary embodiment)

FIG. 29 is a cross-sectional view of a photoelectric conversion apparatus (eighth exemplary embodiment)

FIG. 30 is a cross-sectional view of a photoelectric conversion apparatus (eighth exemplary embodiment)

FIG. 31 is a cross-sectional view of a photoelectric conversion apparatus (ninth exemplary embodiment)

FIG. 32 is a plan view of a photoelectric conversion apparatus (ninth exemplary embodiment)

FIG. 33 is a cross-sectional view of a photoelectric conversion apparatus (ninth exemplary embodiment)

FIG. 34A is a diagram illustrating a configuration of equipment.

FIG. 34B is a diagram illustrating a configuration of equipment.

FIG. 34C is a diagram illustrating a configuration of equipment.

FIG. 35 is a diagram illustrating a configuration of equipment.

### DESCRIPTION OF THE EMBODIMENTS

Hereinafter, each exemplary embodiment will be described with reference to the drawings.

In each exemplary embodiment to be described below, an imaging apparatus will be mainly described as an example of a photoelectric conversion apparatus. Nevertheless, each exemplary embodiment is not limited to the imaging apparatus and can be applied to another example of the photoelectric conversion apparatus. Examples of the photoelectric conversion apparatus include a distance measurement apparatus (apparatus of distance measurement that uses focus detection or time of flight (TOF)), and a photometric apparatus (apparatus of measurement of an incident light amount).

Conductivity types of semiconductor regions and wells, and dopants to be implanted, which will be described below in the following exemplary embodiments, are examples, and are not limited to those described in the exemplary embodiments. The conductivity types and the dopants in the exemplary embodiments can be appropriately changed, and the potentials of semiconductor regions and wells are appropriately changed in accordance with the change.

The conductivity type of a transistor to be described in the following exemplary embodiments is an example, and the conductivity type is not limited to the conductivity type described in the exemplary embodiments. The conductivity type described in the exemplary embodiments can be appropriately changed, and potentials of a gate, a source, and a drain of the transistor are appropriately changed in accordance with the change.

For example, as for a transistor to be operated as a switch, it is sufficient that a low level and a high level of a potential to be supplied to a gate are made reverse to those described in the exemplary embodiments, in accordance with the change of a conductivity type. The conductivity type of a semiconductor region to be described in the following exemplary embodiments is also an example, and the conductivity type is not limited to the conductivity type described in the exemplary embodiments. The conductivity type described in the exemplary embodiments can be appropriately changed, and the potential of the semiconductor region is appropriately changed in accordance with the change.

### First Exemplary Embodiment

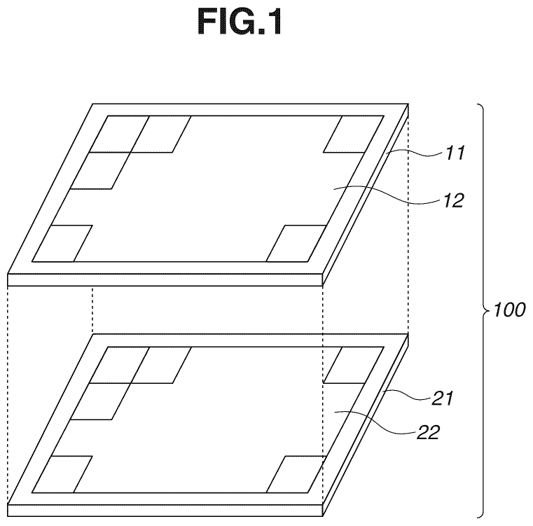

FIG. 1 is a diagram illustrating a configuration of a stack-type photoelectric conversion apparatus 100 according to an exemplary embodiment of the present invention. The photoelectric conversion apparatus 100 is a structure in which two substrates of a sensor substrate 11 (one substrate) and a circuit substrate 21 (the other substrate) are stacked. The photoelectric conversion apparatus 100 is formed by the sensor substrate 11 and the circuit substrate 21 being electrically connected. The sensor substrate 11 includes a first semiconductor layer including a photoelectric conversion element 102 to be described below, and a first wiring structure. The circuit substrate 21 includes a second semiconductor layer including a circuit such as a signal processing unit 103 to be described below, and a second wiring structure. The photoelectric conversion apparatus 100 includes the second semiconductor layer, the second wiring structure, the first wiring structure, and the first semiconductor layer that are stacked in this order. The photoelectric conversion apparatus to be described in each exemplary embodiment is a back-illuminated photoelectric conversion apparatus in which light enters from a first surface, and a circuit substrate is arranged on a second surface.

Hereinafter, the sensor substrate 11 and the circuit substrate 21 will be described as singulated chips, but the sensor substrate 11 and the circuit substrate 21 are not limited to chips. For example, each substrate can be a wafer. Each substrate can also be singulated after being stacked in a wafer state, or can also be singulated into chips and then jointed by stacking the chips.

On the sensor substrate 11, a pixel region 12 is arranged. On the circuit substrate 21, a circuit region 22 for processing signals detected in the pixel region 12 is arranged.

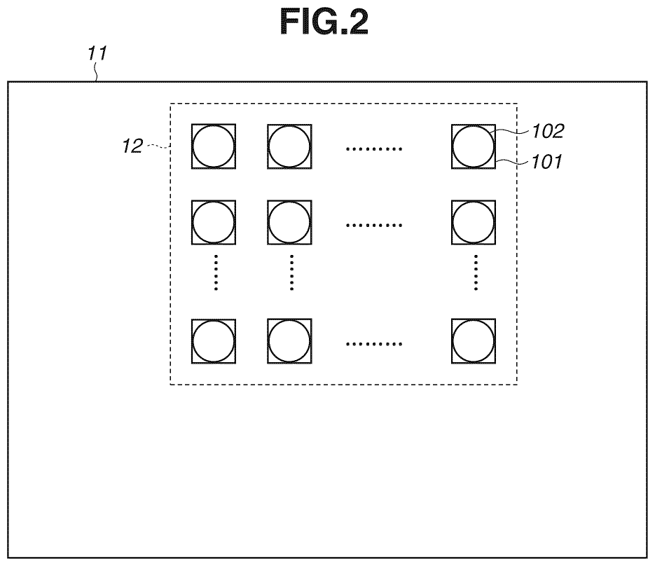

FIG. 2 is a diagram illustrating an arrangement example of the sensor substrate 11. Pixels 101 each including the photoelectric conversion element 102 including an avalanche photodiode (hereinafter, APD) are arranged in a two-dimensional array in a planar view, and form the pixel region 12.

The pixel 101 is typically a pixel for forming an image. In a case where the pixel 101 is used in a time of flight (TOF) sensor, however, an image needs not be always formed. In other words, the pixel 101 can be a pixel for measuring a time at which light reaches and a light amount.

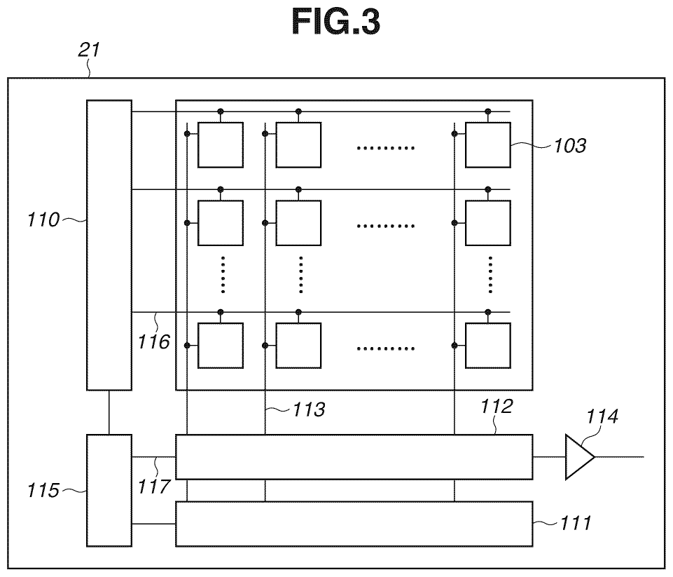

FIG. 3 is a configuration diagram of the circuit substrate 21. The circuit substrate 21 includes the signal processing unit 103 that processes charges photoelectrically converted by the photoelectric conversion element 102 illustrated in FIG. 2, a readout circuit 112, a control pulse generation unit 115, a horizontal scanning circuit unit 111, a signal line 113, and a vertical scanning circuit unit 110.

The photoelectric conversion element 102 illustrated in FIG. 2 and the signal processing unit 103 illustrated in FIG. 3 are electrically connected via a connection line provided for each pixel.

The vertical scanning circuit unit 110 receives a control pulse supplied from the control pulse generation unit 115, and supplies the control pulse to each pixel. The vertical scanning circuit unit 110 uses a logic circuit such as a shift register or an address decoder.

A signal output from the photoelectric conversion element 102 of a pixel is processed by the signal processing unit 103. A counter and a memory are provided in the signal processing unit 103, and a digital value is stored in the memory.

The horizontal scanning circuit unit 111 inputs, to the signal processing unit 103, a control pulse for sequentially selecting each column to read out a signal from the memory of each pixel in which a digital signal is stored.

A signal is output to the signal line 113 from the signal processing unit 103 of a pixel on a selected column that has been selected by the vertical scanning circuit unit 110.

The signal output to the signal line 113 is output to a recording unit or a signal processing unit provided outside the photoelectric conversion apparatus 100 via an output circuit 114.

In FIG. 2, photoelectric conversion elements in a pixel region can also be one-dimensionally arrayed. Even if the number of pixels is one, it is also possible to obtain the effect of the present invention, and a case where the number of pixels is one is also included in the present disclosure. The function of the signal processing unit needs not be always provided for each of all photoelectric conversion elements. For example, one signal processing unit can be shared by a plurality of photoelectric conversion elements, and signal processing can be sequentially performed.

As illustrated in FIGS. 2 and 3, a plurality of signal processing units 103 is arranged in a region overlapping the pixel region 12 in a planar view. The vertical scanning circuit unit 110, the horizontal scanning circuit unit 111, the readout circuit 112, the output circuit 114, and the control pulse generation unit 115 are arranged to overlap a space between the end of the sensor substrate 11 and the end of the pixel region 12 in a planar view. In other words, the sensor substrate 11 includes the pixel region 12, and a non-pixel region arranged around the pixel region 12, and the vertical scanning circuit unit 110, the horizontal scanning circuit unit 111, the readout circuit 112, the output circuit 114, and the control pulse generation unit 115 are arranged in a region overlapping the non-pixel region in a planar view.

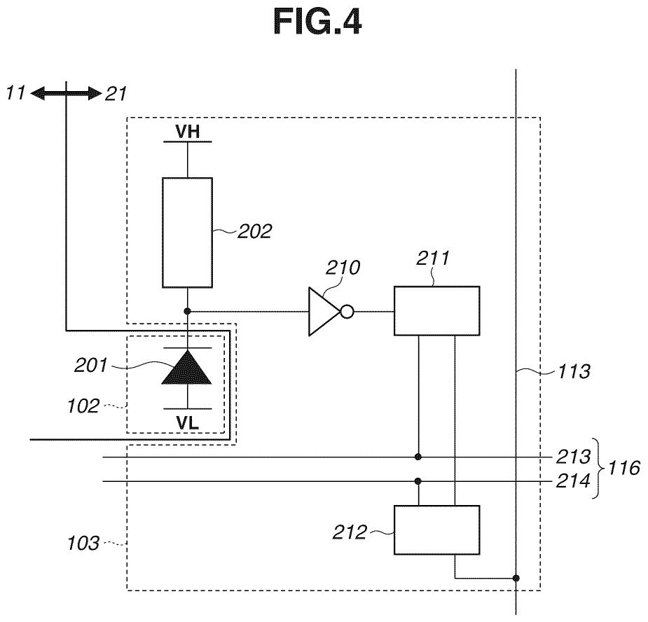

FIG. 4 illustrates an example of a block diagram including an equivalent circuit illustrated in FIGS. 2 and 3.

In FIG. 2, the photoelectric conversion element 102 including an APD 201 is provided on the sensor substrate 11, and other members are provided on the circuit substrate 21.

The APD 201 generates a charge pair corresponding to incident light by photoelectric conversion. A voltage VL (first voltage) is supplied to an anode of the APD 201. A voltage VH (second voltage) higher than the voltage VL supplied to the anode is supplied to a cathode of the APD 201. To the anode and the cathode, inversely-biased voltages for causing the APD 201 to perform an avalanche multiplication operation are supplied. By bringing a state in which such voltages are supplied, a charge generated by incident light causes avalanche multiplication, and an avalanche current is generated.

In a case where inversely-biased voltages are supplied, the APD 201 is operated in a Geiger mode or a linear mode. In the Geiger mode, the APD 201 is operated with a potential difference between the anode and the cathode that is larger than a breakdown voltage. In the linear mode, the APD 201 is operated with a potential difference between the anode and the cathode that is near a breakdown voltage or a voltage difference equal to or smaller than the breakdown voltage.

An APD operated in the Geiger mode will be referred to as a single photon avalanche photodiode (SPAD). For example, the voltage VL (first voltage) is −30 V (volts) and the voltage VH (second voltage) is 1 V. The APD 201 can be operated in the linear mode, or in the Geiger mode. The APD 201 is desirably an SPAD because a potential difference of the SPAD becomes larger as compared with that of an APD in the linear mode, and a pressure resistance effect becomes prominent.

The quench element 202 is connected to the APD 201 and a power source that supplies the voltage VH. The quench element 202 functions as a load circuit (quench circuit) when a signal is multiplied by avalanche multiplication, and has a function of suppressing avalanche multiplication by reducing a voltage to be supplied to the APD 201 (quench operation). The quench element 202 also has a function (recharge operation) of returning a voltage to be supplied to the APD 201, to the voltage VH by flowing a current by an amount corresponding to a voltage drop caused by the quench operation.

The signal processing unit 103 includes a waveform shaping unit 210, a counter circuit 211, and a selection circuit 212. In this specification, the signal processing unit 103 is only required to include any of the waveform shaping unit 210, the counter circuit 211, and the selection circuit 212.

The waveform shaping unit 210 outputs a pulse signal by shaping a potential change of the cathode of the APD 201 that is obtained at the time of photon detection. As the waveform shaping unit 210, an inverter circuit is used, for example. FIG. 4 illustrates an example in which one inverter is used as the waveform shaping unit 210, but a circuit in which a plurality of inverters is connected in series can also be used, or another circuit having a waveform shaping effect can also be used.

The counter circuit 211 counts the number of pulse signals output from the waveform shaping unit 210, and stores a count value. When a control pulse pRES is supplied via a drive line 213, the number of pulse signals that is stored in the counter circuit 211 is reset.

A control pulse pSEL is supplied to the selection circuit 212 from the vertical scanning circuit unit 110 illustrated in FIG. 3, via a drive line 214 illustrated in FIG. 4 (not illustrated in FIG. 3), and electric connection and disconnection are switched between the counter circuit 211 and the signal line 113. The selection circuit 212 includes, for example, a buffer circuit for outputting a signal.

Electric connection can also be switched by arranging a switch such as a transistor between the quench element 202 and the APD 201, or between the photoelectric conversion element 102 and the signal processing unit 103. Similarly, the voltage VH or VL to be supplied to the photoelectric conversion element 102 can also be electrically switched using a switch such as a transistor.

In the present exemplary embodiment, the configuration that uses the counter circuit 211 has been described. Nevertheless, the photoelectric conversion apparatus 100 can acquire a pulse detection timing using a time to digital converter (hereinafter, TDC) and a memory in place of the counter circuit 211. At this time, the generation timing of a pulse signal output from the waveform shaping unit 210 is converted into a digital signal by the TDC. For measuring the timing of a pulse signal, a control pulse pREF (reference signal) is supplied via a drive line to the TDC from the vertical scanning circuit unit 110 illustrated in FIG. 1. Based on the control pulse pREF, the TDC acquires a digital signal indicating an input timing of a signal output from each pixel via the waveform shaping unit 210, as a relative time.

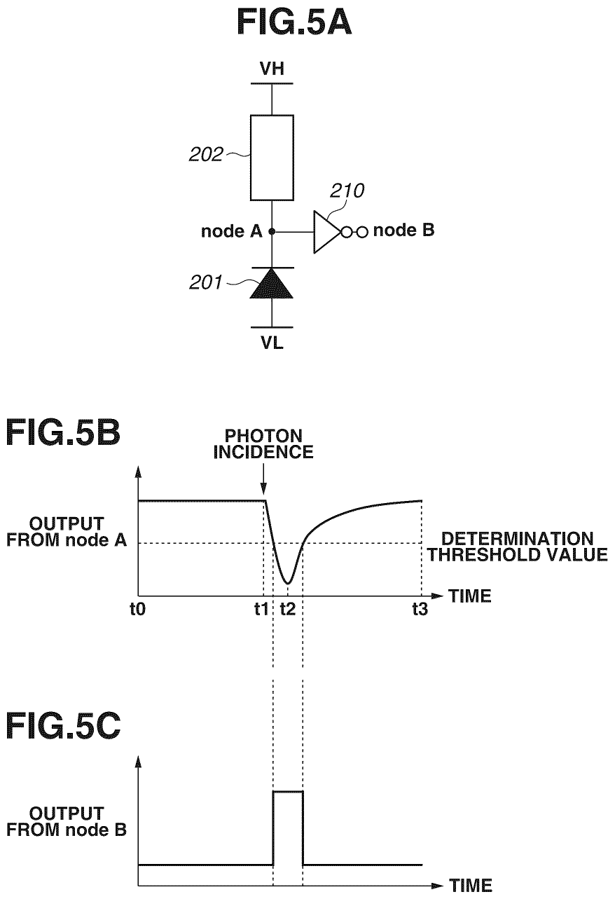

FIGS. 5A, 5B, and 5C are diagrams schematically illustrating a relationship between an operation of an APD and an output signal.

FIG. 5A is a diagram extracting the APD 201, the quench element 202, and the waveform shaping unit 210 illustrated in FIG. 4. In FIG. 5A, an input side of the waveform shaping unit 210 is regarded as a node A and an output side is regarded as a node B. FIG. 5B illustrates a waveform change at the node A in FIG. 5A. FIG. 5C illustrates a waveform change at the node B in FIG. 5A.

During a period from a time t0 to a time t1, a potential difference VH−VL is applied to the APD 201 in FIG. 5A. When a photon enters the APD 201 at the time t1, avalanche multiplication occurs in the APD 201, an avalanche multiplication current flows in the quench element 202, and a voltage at the node A drops. When a voltage drop amount further increases, and a potential difference applied to the APD 201 becomes small, avalanche multiplication of the APD 201 stops at a time t2, and a voltage level at the node A does not drop by a certain fixed value or more. Thereafter, during a period from the time t2 to a time t3, a current compensating for a voltage drop from the voltage VL flows to the node A, and the potential level of the node A is statically settled the original potential level at the time t3. At this time, a portion with an output waveform exceeding a certain threshold value at the node A is subjected to waveform shaping performed by the waveform shaping unit 210, and output as a signal at the node B.

The arrangement of the signal lines 113, and the arrangement of the readout circuit 112 and the output circuit 114 are not limited to those illustrated in FIG. 3. For example, the signal lines 113 can be arranged with extending in a row direction, and the readout circuit 112 can be arranged at the ends of the extending signal lines 113.

Hereinafter, a photoelectric conversion apparatus of each exemplary embodiment will be described.

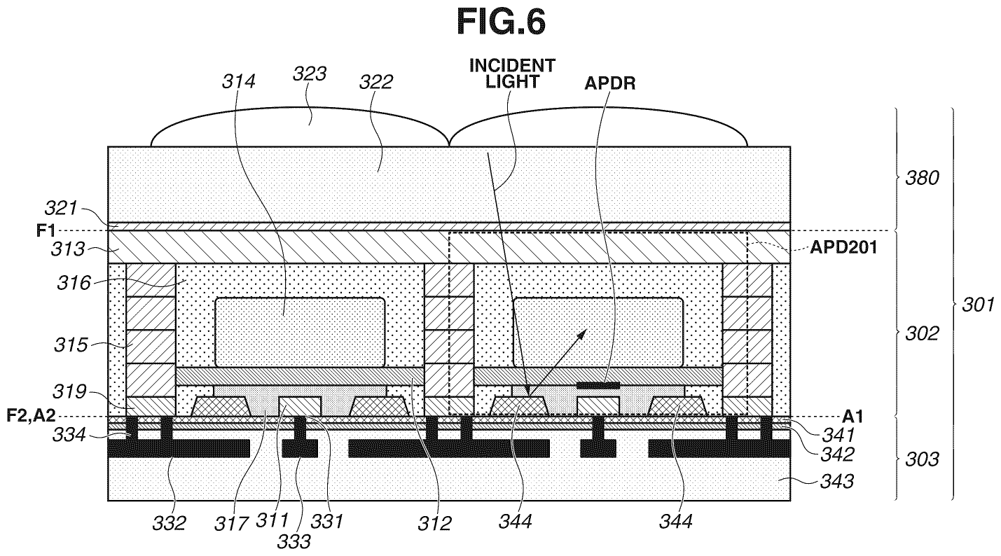

FIG. 6 is a cross-sectional view illustrating a structure of an APD according to the present exemplary embodiment. In this cross-sectional view, the APDs 201 corresponding to two pixels are illustrated. The structures of the two APDs 201 are the same. For the sake of convenience in presenting reference numerals, a reference numeral is allocated to each configuration of one of the two APDs 201, but the configuration is included in both of the two APDs 201.

A semiconductor substrate 301 has a first surface F1 on which light is incident, and a second surface F2 corresponding to the first surface F1. A wiring layer 303 is provided on an upper side (opposing direction to the surface on which light is incident) of the second surface F2. The sensor substrate 11 illustrated in FIG. 1 has the configuration of the semiconductor substrate 301 including the semiconductor layer 302 and the wiring layer 303.

The semiconductor substrate 301 serves as an N-type semiconductor layer including donors as a whole.

The APD 201 includes an N-type semiconductor region 311, a P-type semiconductor region 312, a P-type semiconductor region 313, an N-type semiconductor region 314, an N-type the semiconductor region 316, and an N-type semiconductor region 317. The semiconductor region 316 can have a donor concentration that the semiconductor layer 302 originally has, or an impurity concentration of donors can be increased by further performing ion implantation. Impurity concentrations of the semiconductor regions 311, 314, 316, and 317, which are N-type semiconductor regions, have a relationship of 311>317>314>316. The semiconductor region 311 includes a cathode contact 331. The first voltage (positive voltage) is supplied from a wire 333 to the cathode contact 331 via a contact plug. For example, the first voltage is voltage of approximately 3 V.

The APD 201 includes a region having a function as pixel isolation, and a function of applying a second voltage. In the present exemplary embodiment, this region is defined as a P-type semiconductor region. This region can also be said to be an isolation region in that the function as pixel isolation is provided. Semiconductor regions 315 and 319 provided at depths on a plurality of steps are all P-type semiconductor regions. The semiconductor region 319 includes an anode contact 334. The second voltage (negative voltage) is supplied from a wire 332 to the anode contact 334 via a contact plug. For example, the second voltage is a voltage of approximately −30 V.

An example in which the P-type semiconductor regions 315 on a plurality of steps are provided at depths of four steps is illustrated, but the example is not limited to this example.

The second voltage is supplied to the semiconductor region 312 from the semiconductor region 315. Thus, a voltage exceeding an avalanche breakdown voltage is applied to a PN junction generated between the semiconductor region 317 and the semiconductor region 312. Avalanche multiplication is thereby implemented. The PN junction becomes an avalanche multiplication region APDR. The avalanche multiplication occurs by electrons (seed electrons) generated in the semiconductor region 316 or the semiconductor region 314 passing through the avalanche multiplication region APDR. Thus, electrons much more than the seed electrons generated in the semiconductor region 316 or the semiconductor region 314 are carried to the semiconductor region 311.

The APD 201 also includes the P-type semiconductor region 313. The semiconductor region 313 has a role of reducing dark current components generated mainly due to a defect on the surface of a semiconductor layer F1 and entering the semiconductor region 316.

A pinning film (fixed charge film) 321 is provided on an incidence plane side of the first surface F1. The pinning film 321 is a film having a negative fixed charge. By the pinning film 321, a positive charge is generated in a region near the first surface F1 in the semiconductor layer 302. The pinning film 321 accordingly has a role of reducing dark current components generated mainly due to a defect on the surface of a semiconductor layer F1 and entering the semiconductor region 316, together with the P-type semiconductor region 313. The pinning film is typically an aluminum oxide film, but can be a film containing at least one of aluminum oxide and tantalum oxide. In a case where a stacked film of an aluminum oxide film and a tantalum oxide film is used, it is desirable that the aluminum oxide film and tantalum oxide film are stacked in this order from a position closer to the first surface F1.

On the pinning film 321, a planarization layer 322 is formed. The planarization layer 322 can be a film including at least one of a silicon oxide film, a silicon nitride film, or a silicon oxynitride film, or can have a configuration of a stacked film of a plurality of films. On the planarization layer 322, a microlens 323 is provided. The microlens 323 condenses light and makes the light incident on the APD 201. An optical layer 380 includes the pinning film 321, the planarization layer 322, and the microlens 323. A color filter can also be provided between the microlens 323 and the planarization layer 322. By providing color filters with different colors among a plurality of pixels, color information can also be acquired. Between the pinning film 321 and the planarization layer 322, a film having another function can also be provided. For example, the sensitivity of the APD 201 can also be enhanced by providing an antireflection film.

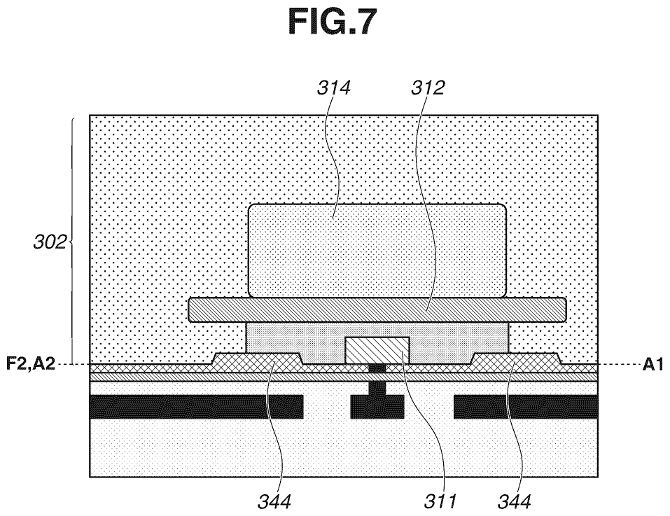

The semiconductor layer 302 includes a dielectric member 344. The dielectric member 344 can be formed with a LOCal Oxidation of Silicon (LOCOS) process or a Shallow Trench Isolation (STI) process. Here, a structure in which the dielectric member 344 is formed with the STI process. Typically, the dielectric member 344 mainly contains silicon oxide. In whichever of a case where the dielectric member 344 is formed with the LOCOS process and a case where the dielectric member 344 is formed with the STI process, the dielectric member 344 has a portion extending inside the semiconductor layer 302. FIG. 7 illustrates a case where the dielectric member 344 is formed with the LOCOS process. Even in the dielectric member 344 illustrated in FIG. 7, the dielectric member 344 has a portion extending inside the semiconductor layer 302. The dielectric member 344 illustrated in FIG. 7 differs from that in the case where the dielectric member 344 is formed with the STI process, in that a portion extending to a position closer to a wiring layer than the second surface F2 is also included. The dielectric member 344 illustrated in FIG. 6 also extends up to a position where a depth from the second surface F2 is deeper than that of the semiconductor region 311. In contrast, the dielectric member 344 illustrated in FIG. 7 extends up to a position where a depth from the second surface F2 is shallower than that of the semiconductor region 311. Both of the dielectric members 344 illustrated in FIGS. 6 and 7 extend in common up to a position where a depth from the second surface F2 is shallower than that of the semiconductor region 312.

The semiconductor regions described so far will be summarized. In the present exemplary embodiment, an N-type conductivity type is a first conductivity type, and a P-type conductivity type is a second conductivity type. A first semiconductor region of the first conductivity type that is provided at a first depth from the first surface F1 is the semiconductor region 314. A second semiconductor region of the second conductivity type that exists at a position closer to the second surface F2 than the first semiconductor region is the semiconductor region 312. A third semiconductor region of the first conductivity type that exists at a position closer to the second surface F2 than the second semiconductor region, to which a first voltage is applied is the semiconductor region 311. A region to which a second voltage different from the first voltage is applied is the semiconductor region 319. A fourth semiconductor region of the first conductivity type that is provided between the region and the third semiconductor region is at least one of a portion of the semiconductor region 316 at a depth where the semiconductor region 319 is provided, and the semiconductor region 317. A dielectric member that is positioned in a portion overlapping at least the fourth semiconductor region in a planar view with respect to the second surface F2, and that includes a portion extending at least from the second surface F2 to the inside of the semiconductor layer is the dielectric member 344.

The description will return to FIG. 6. FIG. 6 illustrates a partial pathway of incident light. Electrons generated in the pathway of incident light illustrated in FIG. 6 do not pass through the avalanche multiplication region APDR, and thereby the electrons do not contribute to the sensitivity of the APD 201. In a case where the dielectric member 344 is not provided, incident light through the pathway does not contribute to the sensitivity of the APD 201, and the sensitivity has lowered. In contrast, in the present exemplary embodiment, it is possible to reflect incident light that has entered through the pathway, to the semiconductor region 314 by providing the dielectric member 344. With this configuration, the reflected incident light can generate signal charges (electrons) in the semiconductor region 314. Electrons generated in the semiconductor region 314 can pass through the avalanche multiplication region APDR. Providing the dielectric member 344 can thus improve the sensitivity of the APD 201. In a case where the dielectric member 344 is not provided, a semiconductor region is positioned in a corresponding portion. In this semiconductor region, the seed charge is unlikely to enter the avalanche multiplication region APDR even if seed charge is generated. That is, the semiconductor region becomes an insensitive region not contributing to avalanche multiplication even if light enters the region. Seed charges generated in the semiconductor region 311 and the semiconductor region 312 sometimes enter an alternative semiconductor region existing in a case where the dielectric member 344 is not provided. Even in this case, the incident seed charges does not contribute to avalanche multiplication. Providing the dielectric member 344 in place of such a semiconductor region serving as an insensitive region is unlikely to cause a deterioration in sensitivity. By reducing the insensitive region, it is possible to reduce seed charges generated in the semiconductor region 311 and the semiconductor region 312 from entering the insensitive region. That is, because it is possible to reduce seed charges entering the insensitive region, and the seed charges can be easily guided to the avalanche multiplication region APDR, the seed charges contribute to improvement in sensitivity.

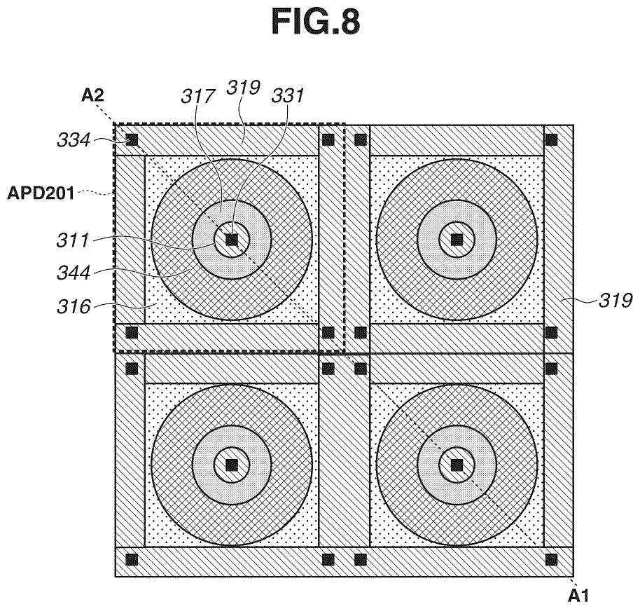

FIG. 8 is a plan view of the structure illustrated in FIG. 6 that is viewed from the second surface F2. In FIG. 8, similar members as the members illustrated in FIG. 6 are assigned the same reference numerals as the reference numerals allocated in FIG. 6. FIG. 8 illustrates the APDs 201 having four pixels on two rows and two columns. FIG. 6 is a cross-sectional view taken along an A1-A2 line illustrated in FIG. 8.

As illustrated in FIG. 8, the dielectric member 344 is provided in a ring shape to surround the semiconductor region 311. This shape makes it possible to desirably reflect light rays at various angles that enter the microlens 323, to the semiconductor region 314.

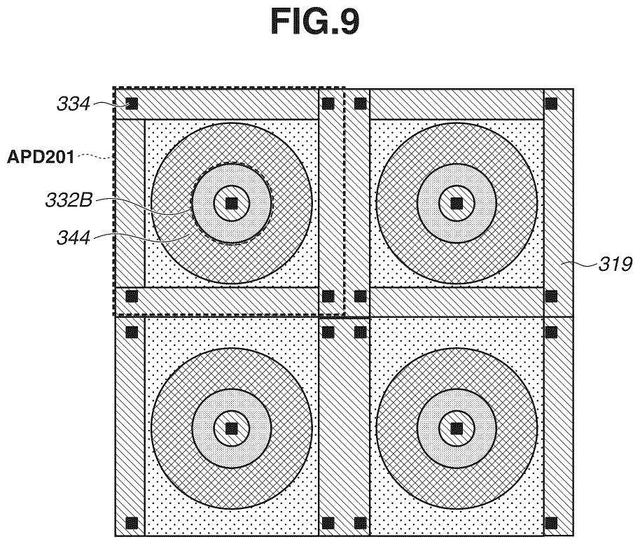

In FIG. 9, the reference numerals of a part of the members illustrated in FIG. 8 are omitted, and an opening 332B, which is an opening portion of the wire 332, is illustrated instead. In a planar view viewed from the second surface F2, an end portion of the opening 332B is arranged at the same position as a center-side end portion of the dielectric member 344. In other words, a portion excluding the opening 332B is a region where the wire 332 is arranged. That is, in a planar view from the second surface F2, the wire 332 and the dielectric member 344 mutually include overlapping portions. By the wire 332 being provided at a position overlapping the dielectric member 344 in a planar view, the wire 332 can reflect light transmitted through the dielectric member 344, to enter the semiconductor region 314. With this configuration, it is possible to improve the sensitivity of the APD 201.

In the arrangement example illustrated in FIG. 9, the entire region of the dielectric member 344 overlaps the wire 332 in a planar view. The arrangement example is not limited to this example, and improvement effect of the sensitivity of the APD 201 can be obtained by the wire 332 overlapping at least part of the dielectric member 344 in a planar view.

Next, a manufacturing method of the photoelectric conversion apparatus described in the present exemplary embodiment with reference to FIGS. 6 and 8 will be described.

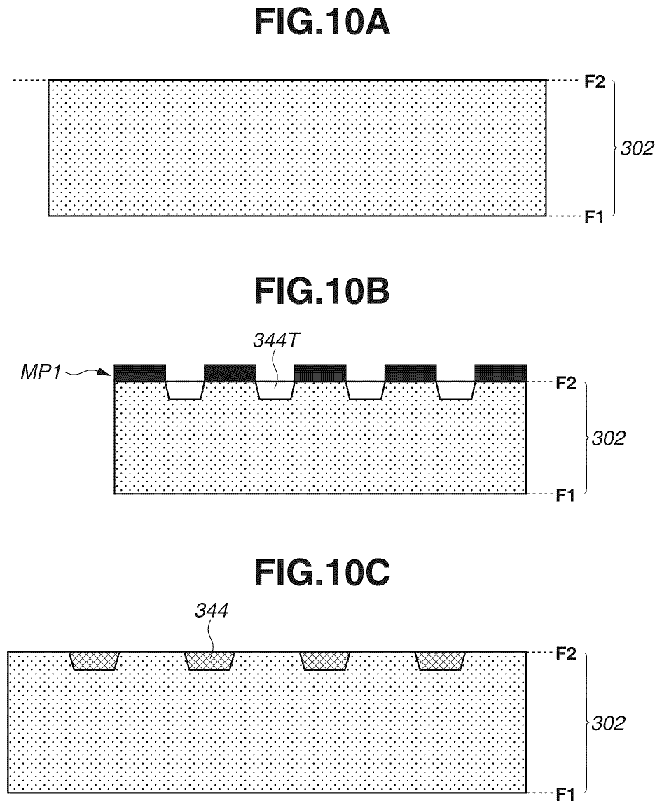

FIGS. 10A to 10C are diagrams illustrating a part of processes of the manufacturing method of the photoelectric conversion apparatus according to the present exemplary embodiment.

As illustrated in FIG. 10A, a silicon wafer including the N-type semiconductor layer 302 into which donor is introduced as a whole is prepared.

As illustrated in FIG. 10B, after a mask pattern MP1 is formed by photolithography, a trench portion 344T is formed by reactive ion etching such as dry etching. The trench portion 344T is formed in a location where the dielectric member 344 is to be provided.

After the mask pattern MP1 is removed, silicon oxide is deposited in the trench portion 344T with chemical vapor deposition (CVD) as illustrated in FIG. 10C. The dielectric member 344 is then formed by removing excess silicon oxide with chemical mechanical polishing (CMP). Here, the dielectric member 344 is formed before the other semiconductor regions 311 to 315 and 319 are formed. It is thus possible to sufficiently perform annealing treatment after the dielectric member 344 is formed. In a case where the dielectric member 344 is formed after the semiconductor regions 311 to 315 and 319 are formed, if annealing treatment is performed, it is difficult to perform sufficient annealing treatment because impurities of the semiconductor regions disperse and it becomes difficult to manufacture a device with an appropriate density distribution. In the present exemplary embodiment, it is possible to perform sufficient annealing treatment by forming the dielectric member 344 prior to the formation of each semiconductor region. This configuration can reduce dark current attributed to the defect of the semiconductor layer 302 that is likely to occur due to the formation of the dielectric member 344.

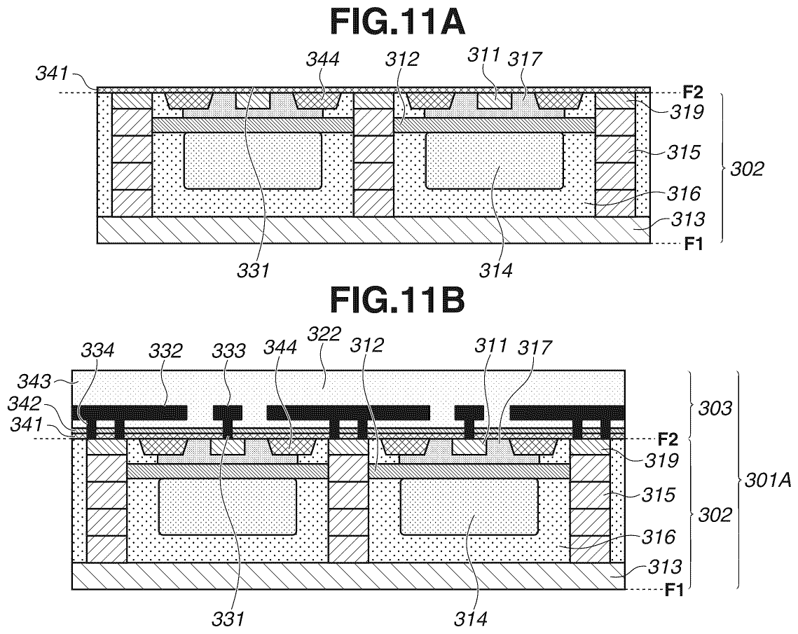

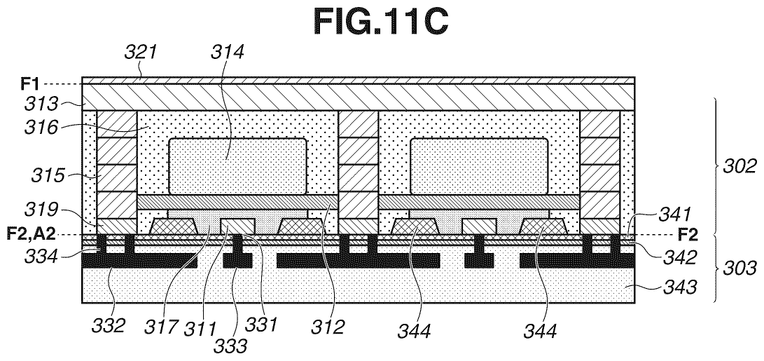

As illustrated in FIG. 11A, the semiconductor regions 311 to 315 and 319 are formed with ion implantation. In this case, it is desirable to perform the ion implantation of the semiconductor regions 311 to 315 and 319 after a silicon oxide film 341 is formed first. This method can reduce the damages to the semiconductor layer 302 that are caused by ion implantation.

As illustrated in FIG. 11B, after a silicon nitride film 342 is formed, the wiring layer 303 including the cathode contact 331, the anode contact 334, the wire 333, the wire 332, and the planarization layer 322 is formed. Through this process, a semiconductor substrate 301A before being formed into a stacked sensor (structure) is formed.

After this process, a stacked sensor is formed by the semiconductor substrate 301A (one substrate) being bonded with the circuit substrate 21 (the other substrate) illustrated in FIG. 1. Various bonding methods can be employed in the bonding. For example, silicon oxide films are formed on bonded surfaces of the semiconductor substrate 301A and the circuit substrate 21. Recesses are formed in part of the silicon oxide films of the semiconductor substrate 301A and the circuit substrate 21, and conductive members are buried in the recesses. The conductive members are electrically connected with a wiring layer positioned in a lower layer thereof via a via plug. As the conductive members, metal materials such as copper, aluminum, or tungsten are used. The respective conductive members of the semiconductor substrate 301A and the circuit substrate 21 are bonded. The silicon oxide films on the respective bonded surfaces of the semiconductor substrate 301A and the circuit substrate 21 are also bonded. That is, the bonding of the silicon oxide films and the bonding of the conductive members are formed on the bonded surface. This is also referred to as hybrid bonding. With the bonding, bonding and electric connection of the semiconductor substrate 301A and the circuit substrate 21 are performed.

FIG. 11C illustrates a process of the semiconductor substrate 301A after bonding. Unlike FIG. 11B, FIG. 11C illustrates the semiconductor substrate 301A in such a manner that the first surface F1 is positioned on the upper side and the second surface F2 is positioned on the lower side. As illustrated in FIG. 11C, the pinning film 321 is formed with atomic layer deposition (ALD) on the first surface F1, which is an incidence plane side surface of the semiconductor substrate 301A after bonding. Thereafter, forming the planarization layer 322 and the microlens 323 can manufacture the photoelectric conversion apparatus with the structure illustrated in FIG. 6.

### Second Exemplary Embodiment

The present exemplary embodiment will be described based mainly on a difference from the first exemplary embodiment. The present exemplary embodiment differs in the structure of the dielectric member 344.

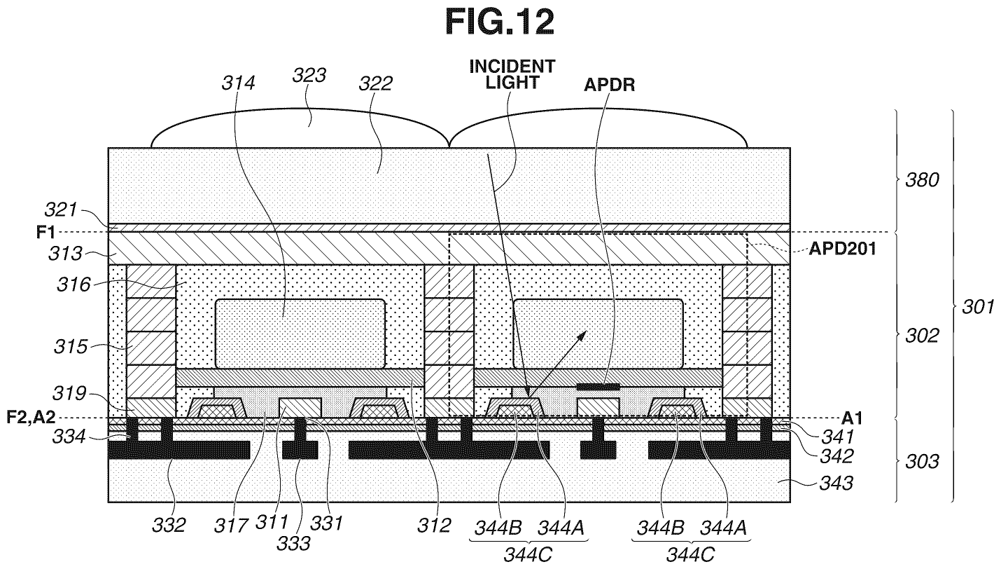

FIG. 12 is a cross-sectional view of a photoelectric conversion apparatus according to the present exemplary embodiment. In FIG. 12 and the subsequent diagrams according to the exemplary embodiments not limited to the present exemplary embodiment, members having the same functions as the members described in the first exemplary embodiment are assigned the same reference numerals as the reference numerals used in the first exemplary embodiment. A dielectric member 344C of the present exemplary embodiment includes a first portion 344A and a second portion 344B. The second portion 344B is provided inside the first portion 344A. The first portion 344A and the second portion 344B are each formed of a dielectric material. For example, the first portion 344A is a silicon nitride film or a silicon oxynitride film, and the second portion 344B is a silicon oxide film or a silicon oxynitride film. In a case where both of the first portion 344A and the second portion 344B are silicon oxynitride films, it is sufficient that contained amounts of nitrogen elements are made different between the first portion 344A and the second portion 344B. For example, it is desirable that the contained amounts satisfy the relationship of the first portion 344A>the second portion 344B. With such a configuration, it is possible to cause reflection of incident light to easily occur on the boundary surface of the first portion 344A and the second portion 344B. It is thus possible to guide large amount of light to the semiconductor region 314, and it is accordingly possible to improve the sensitivity of the APD 201. As a contained amount of a nitrogen element increases, a refractive index of a film becomes higher. A refractive index difference attributed to the difference in contained amount of the nitrogen element can desirably reflect incident light.

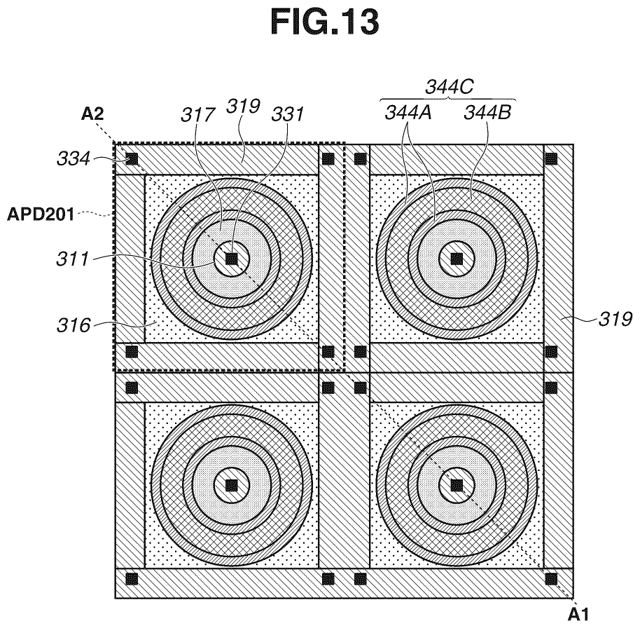

FIG. 13 is a plan view according to the present exemplary embodiment that is viewed from the second surface F2. FIG. 12 is a cross-sectional view taken along an A1-A2 line illustrated in FIG. 13. The first portion 344A and the second portion 344B are both formed into a ring shape. When viewed from the cathode contact 331, the first portion 344A is arranged on the outermost circumference of the dielectric member 344C. On the inner circumference of the outermost circumference, the second portion 344B is arranged. The first portion 344A is arranged on the innermost circumference. This structure can desirably reflect incident light to the semiconductor region 314, as described above.

### Third Exemplary Embodiment

The present exemplary embodiment will be described centering on a difference from the first exemplary embodiment.

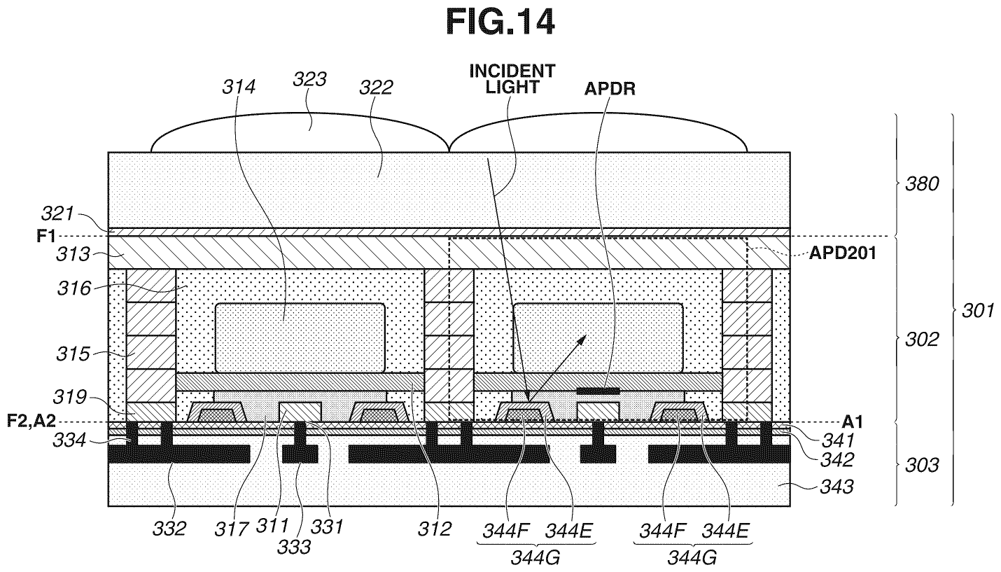

FIG. 14 is a cross-sectional view of a photoelectric conversion apparatus according to the present exemplary embodiment. In the present exemplary embodiment, a dielectric member 344G includes a third member 344E, and a fourth member 344F formed inside the third member 344E. The third member 344E is an insulating film, and is an insulating film such as a silicon oxide film, a silicon nitride film, or a silicon oxynitride film. In contrast, the fourth member 344F is a metal member, and can be a metal material such as tungsten, cobalt, or ruthenium, for example. As to the fourth member 344F, a metal material that reflects light can be desirably employed. This configuration can make the fourth member 344F. which is a metal member, desirably reflect incident light to the semiconductor region 314.

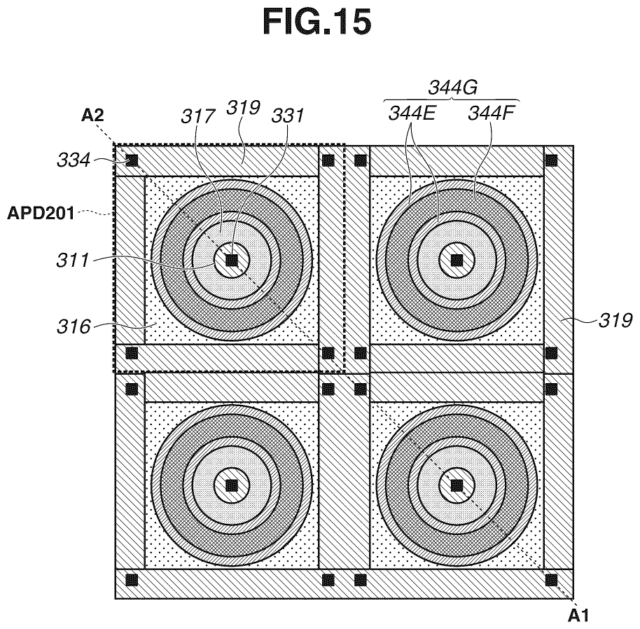

FIG. 15 is a plan view according to the present exemplary embodiment that is viewed from the second surface F2. FIG. 14 is a cross-sectional view taken along an A1-A2 line illustrated in FIG. 15. The third member 344E and the fourth member 344F are both formed into a ring shape. When viewed from the cathode contact 331, the third member 344E is arranged on the outermost circumference of the dielectric member 344G. On its inner circumference of the outermost circumference, the fourth member 344F is arranged. The third member 344E is arranged on the innermost circumference. This structure can desirably reflect incident light to the semiconductor region 314, as described above.

### Fourth Exemplary Embodiment

The present exemplary embodiment will be described mainly based on a difference from the first exemplary embodiment.

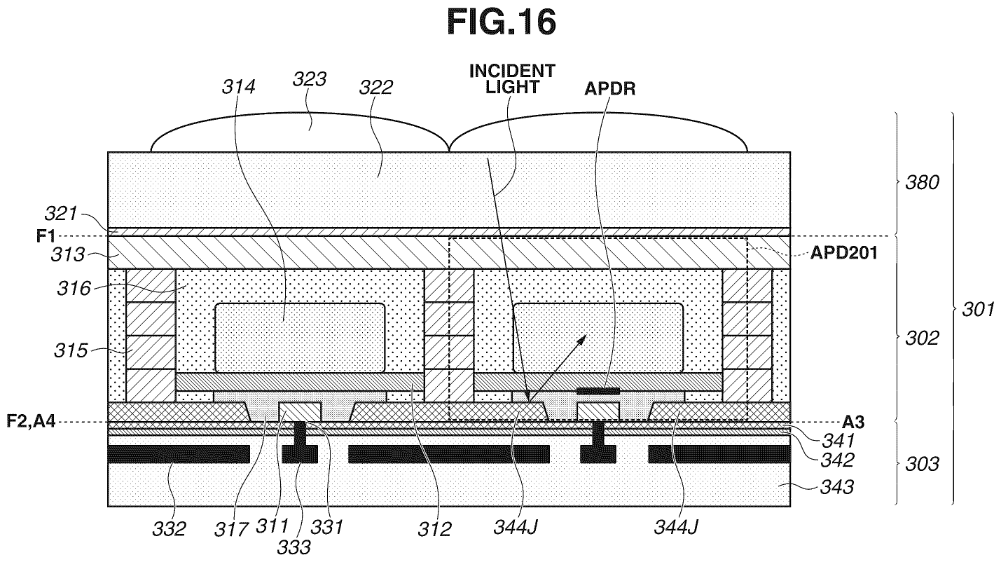

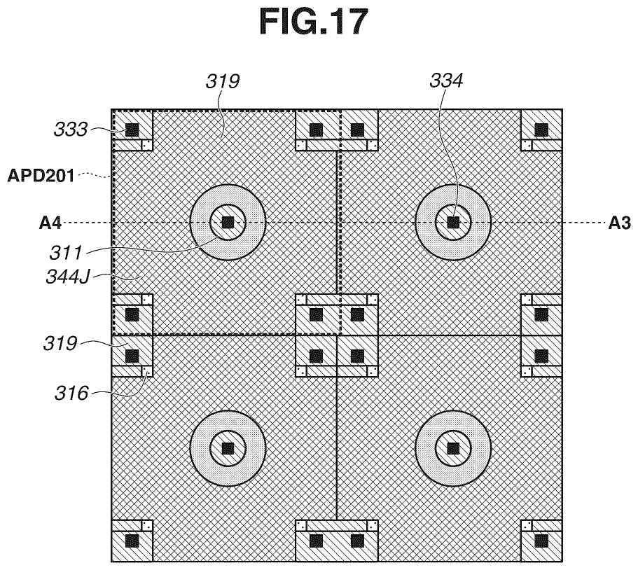

FIG. 16 is a cross-sectional view of a photoelectric conversion apparatus according to the present exemplary embodiment. This ross-sectional view is a cross-sectional view taken along at the position of an A3-A4 line illustrated in FIG. 17. In the present exemplary embodiment, a dielectric member 344J is formed over a plurality of APDs 201. This configuration can improve the sensitivity of the APD 201 because this configuration can make a region where incident light is reflected to a broader range than that in the first exemplary embodiment.

FIG. 17 is a plan view according to the present exemplary embodiment that is viewed from the second surface F2. FIG. 16 is a cross-sectional view taken along an A3-A4 line illustrated in FIG. 17. FIG. 17 illustrates the dielectric member 344 formed over the APDs 201 on two rows and two columns. Actually, the dielectric member 344 can be formed over all APDs 201 provided in the semiconductor layer 302 that function as effective pixels. This structure can desirably reflect incident light to the semiconductor region 314, as described above.

### Fifth Exemplary Embodiment

In the present exemplary embodiment, a modified example of the arrangement of the dielectric member 344 according to the first exemplary embodiment will be described.

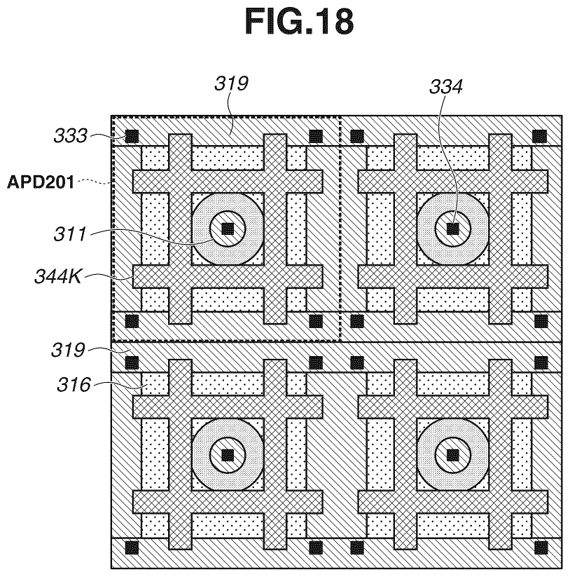

FIG. 18 is a plan view illustrating the arrangement of a dielectric member 344K according to one modified example that is viewed from the second surface F2. The arrangement has a configuration in which the dielectric member 344K is provided in a lattice pattern. FIG. 18 illustrates a configuration in which the lattice-shaped dielectric member 344K is provided inside one APD 201. As another configuration, the lattice-shaped dielectric member 344K can continuously be formed over a plurality of APDs 201 without being separated between a plurality of APDs 201.

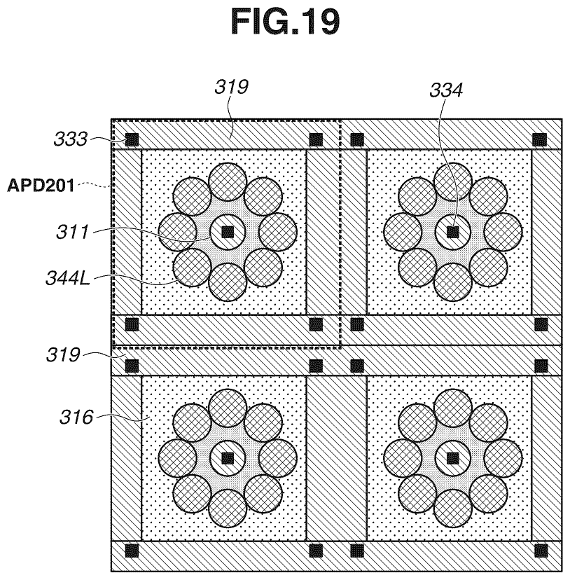

FIG. 19 is a plan view illustrating the arrangement of a dielectric member 344L according to another modified example that is viewed from the second surface F2. The arrangement has a configuration in which circular dielectric members 344L are provided on the circumference centered on the anode contact 334.

Even these configurations can desirably guide incident light to the semiconductor region 314 by reflecting the incident light, and improve the sensitivity of the APD 201.

### Sixth Exemplary Embodiment

In the present exemplary embodiment, a configuration in which the present disclosure is applied to the configuration discussed in PTL-1 will be described. A difference from the first exemplary embodiment will be mainly described.

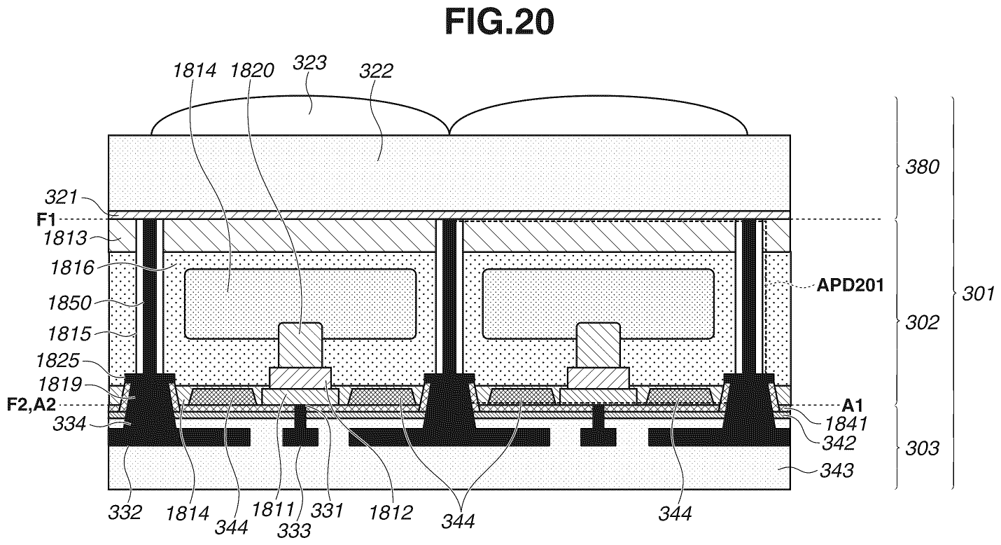

FIG. 20 is a cross-sectional view of a photoelectric conversion apparatus according to the present exemplary embodiment. A cross-sectional position is a position similar to the A1-A2 line described in the first exemplary embodiment.

An N-type semiconductor region 1814 is provided inside a P-type semiconductor region 1816. Photoelectric conversion is mainly performed in a region of the N-type semiconductor region 1814. An N-type semiconductor region 1820 has an impurity concentration (donor concentration) higher than that of a semiconductor region 1814. The APD 201 includes a P-type semiconductor region 1812 and an N-type semiconductor region 1811. A cathode contact 331 is connected to the N-type semiconductor region 1811. In an anode portion, an anode electrode 1819 is embedded in a groove provided inside the semiconductor layer 302. A silicon oxide film 1841 is formed to surround the outer circumference of the anode electrode 1819. The anode electrode 1819 is in contact with an anode contact 1825. A light shielding portion 1850 is provided from the side of the first surface F1 to shield light between a plurality of APDs 201. An insulating film 1815 is provided to surround the light shielding portion 1850. The insulating film 1815 can include the pinning film 321.

Charges generated by the photoelectric conversion move from the semiconductor region 1814 to the semiconductor region 1820 to reach the semiconductor region 1812. A voltage applied to the anode contact 1825 is supplied to the semiconductor region 1812 via the P-type semiconductor region 1816. Thus, avalanche multiplication occurs at a PN junction between the semiconductor region 1812 and the semiconductor region 1811.

In the present exemplary embodiment, the anode electrode 1819 corresponds to a region to which a second voltage different from the first voltage applied to the semiconductor region 1811 is applied.

In this configuration, the dielectric member 344 is also formed. The dielectric member 344 is provided between the anode electrode 1819 and the semiconductor region 1811. In this configuration, the dielectric member 344 can also reflect incident light and guide the incident light to the semiconductor region 1814. This configuration can improve the sensitivity of the APD 201.

In the present exemplary embodiment, an example has been described in which the light shielding portion 1850 and the anode contact 1825 are not connected. However, the light shielding portion 1850 and the anode contact 1825 can also be connected. This configuration can supply a voltage corresponding to the second voltage, to the semiconductor region 1816 more easily because the second voltage is also supplied to the light shielding portion 1850.

### Seventh Exemplary Embodiment

The present exemplary embodiment will be described centering on a difference from the first exemplary embodiment.

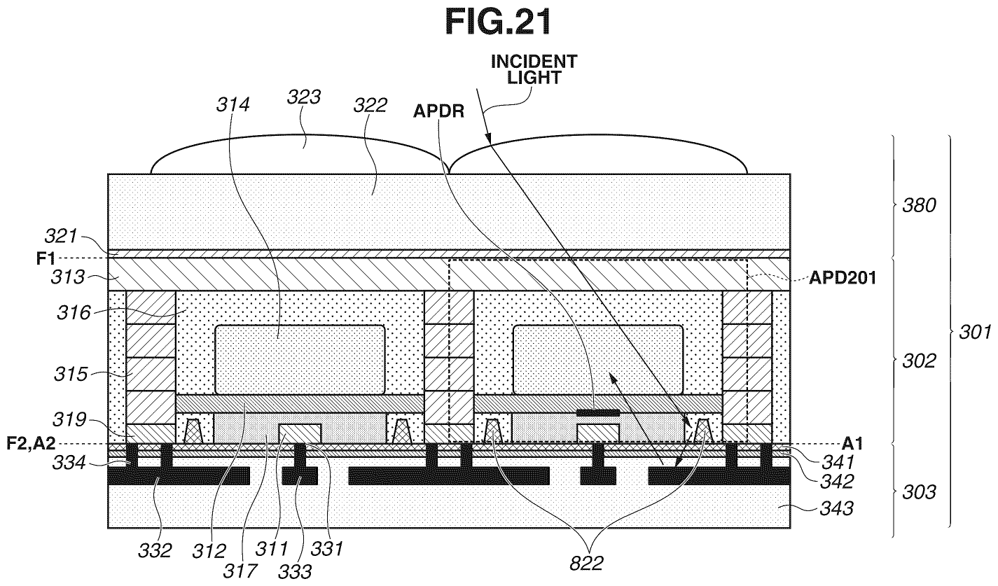

FIG. 21 is a cross-sectional view illustrating a structure of an APD according to the present exemplary embodiment. This cross-sectional view illustrates APDs 201 corresponding to two pixels. The structures of the two APDs 201 are the same. For the sake of convenience in presenting reference numerals, a reference numeral is allocated to each configuration of one of the two APDs 201, but the configuration is included in both of the two APDs 201. In FIG. 21, the members having the same functions as the members illustrated in FIG. 6 are assigned the same reference numerals as the reference numerals used in FIG. 6.

The APD of the present exemplary embodiment includes a trench portion 822. The trench portion 822 has a structure of the shallow trench isolation (STI). The trench portion 822 includes a silicon compound. The trench portion 822 typically includes a silicon oxide film. The trench portion 822 extends from the second surface F2 toward the first surface F1. An end portion of the trench portion 822 that is closest to the first surface F1 exists at a position closer to the second surface F2 than the semiconductor region 312. That is, the end portion of the trench portion 822 that is closest to the first surface F1 is positioned at a depth between the semiconductor region 312 and the second surface F2. The configuration is not limited to this configuration, and the trench portion 822 can extend from the second surface F2 up to a depth position inside the semiconductor region 312. In addition, the APD 201 can have a configuration not including the semiconductor region 312. By including the trench portion 822, it is possible to reflect incident light and guide the incident light again to the semiconductor layer 302 by reflection with the wire 332. This configuration can improve the sensitivity of the APD.

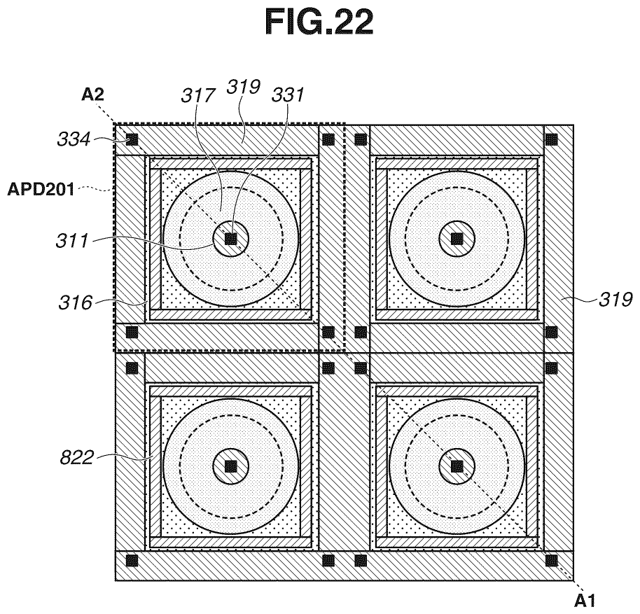

FIG. 22 is a plan view illustrating the structure of the APD. FIG. 21 is a cross-sectional view taken along an Al-A2 line illustrated in FIG. 22.

The trench portion 822 is provided at a position between the semiconductor region 317 and the semiconductor region 319. The trench portion 822 is provided in a rectangular shape so as to surround the circular semiconductor region 317. The trench portion 822 is provided between the respective semiconductor regions 317 of two APDs 201 neighboring in a row direction. The trench portion 822 is also provided between the respective semiconductor regions 317 of two APDs 201 neighboring in a column direction. This configuration thereby enables the trench portion 822 to desirably reflect incident light to the wire 332.

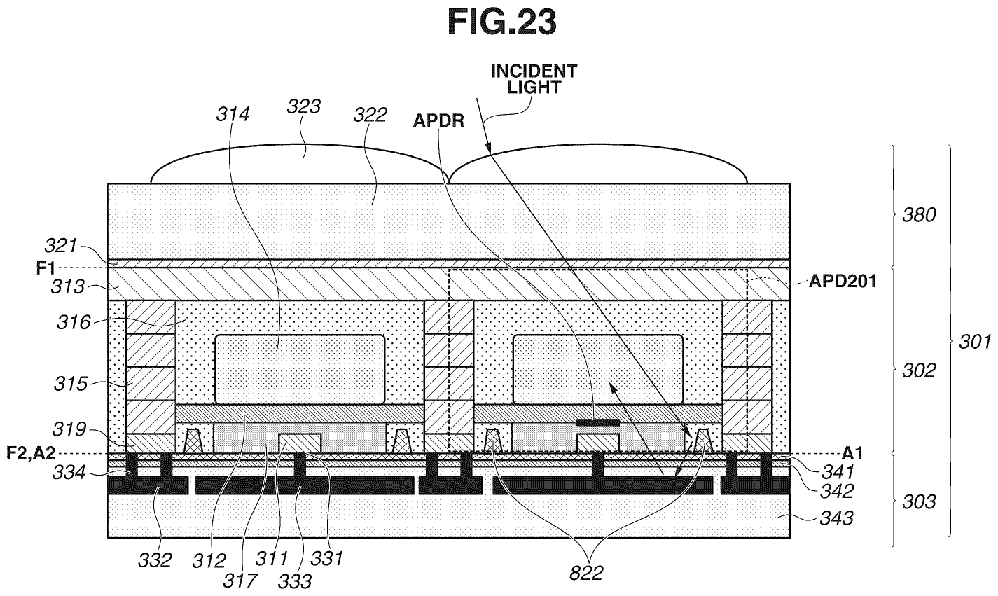

In the present exemplary embodiment, as illustrated in FIG. 21, the wire 332 is arranged to overlap the trench portion 822 in a planar view (planar view viewed from the second surface F2). As another example, as illustrated in FIG. 23, the wire 333 can be arranged so as to overlap the trench portion 822 in a planar view. In this case, light reflected by the trench portion 822 enters the semiconductor layer 302 via the wire 333.

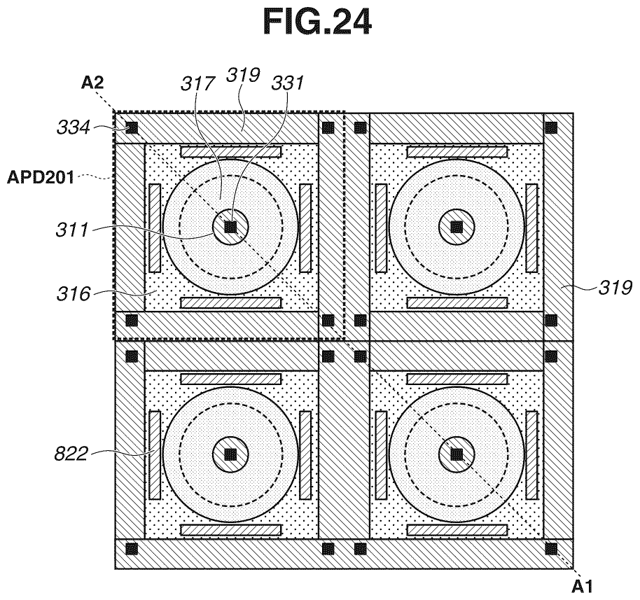

In the present exemplary embodiment, the trench portion 822 is arranged in a rectangular shape so as to surround the semiconductor region 317 as illustrated in FIG. 22 as an example. The example is not limited to this example, and an example illustrated in FIG. 24 can also be employed. The trench portion 822 is provided between the respective semiconductor regions 317 of two APDs 201 neighboring in the row direction. The trench portion 822 is also provided between the respective semiconductor regions 317 of two APDs 201 neighboring in the column direction. In contrast, the trench portion 822 is not provided at a position where a diagonal line of the APD 201 passes through, and the semiconductor region 316 is provided at the position at the depth. This configuration can obtain an effect of improving the sensitivity of the APD.

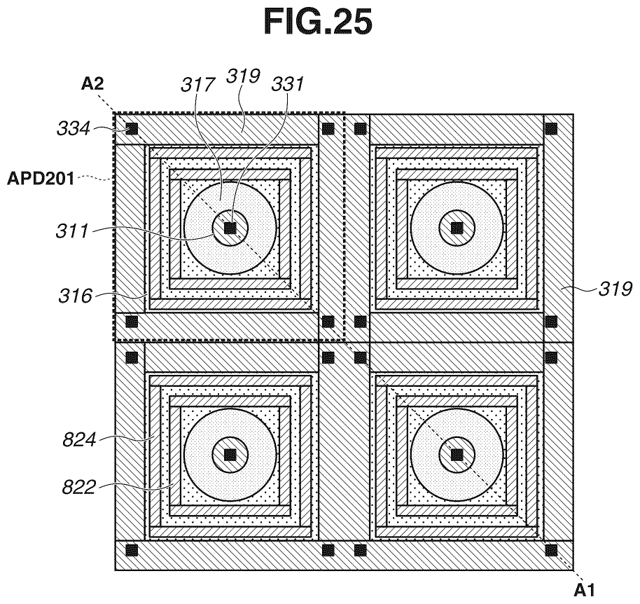

As another configuration, as illustrated in FIG. 25, another trench portion 824 can also be provided so as to further surround the rectangular trench portion 822. As illustrated in FIG. 24, a configuration can be employed in which the trench portions 822 and 824 are not provided at a position where a diagonal line of the APD 201 passes through, and the semiconductor region 316 is provided at the depth position.

### Eighth Exemplary Embodiment

The present exemplary embodiment will be described centering on a difference from the seventh exemplary embodiment.

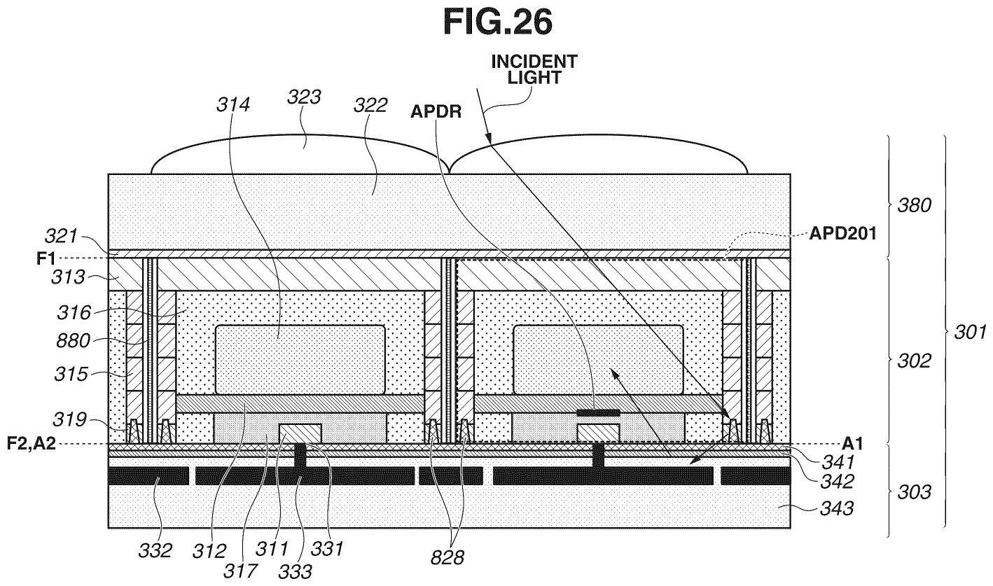

FIG. 26 is a cross-sectional view of an APD according to the present exemplary embodiment. The APD according to the present exemplary embodiment includes a trench portion 880 extending from the first surface F1 toward the second surface F2. The trench portion 880 has a deep trench isolation (DTI) structure. The inside of the trench portion 880 can be filled with a silicon compound, or air can be contained thereinside. Alternatively, metal can be buried in the trench portion 880. In a case where metal is buried, it is possible to enhance light shielding performance obtained by the trench portion 880, and reduce crosstalk from one APD to the other APD. The crosstalk occurs by avalanche light being emitted from one APD and entering the other APD. The trench portion 880 can prevent the avalanche light from entering the other APD. The trench portion 880 is provided inside the semiconductor region 315 serving as a sixth semiconductor region. The semiconductor region 315 is a semiconductor region provided between a plurality of APDs. A trench portion 828 (dielectric member) is provided inside the semiconductor region 319. In the present exemplary embodiment, the trench portion 939 further includes a portion arranged in the semiconductor region 315.

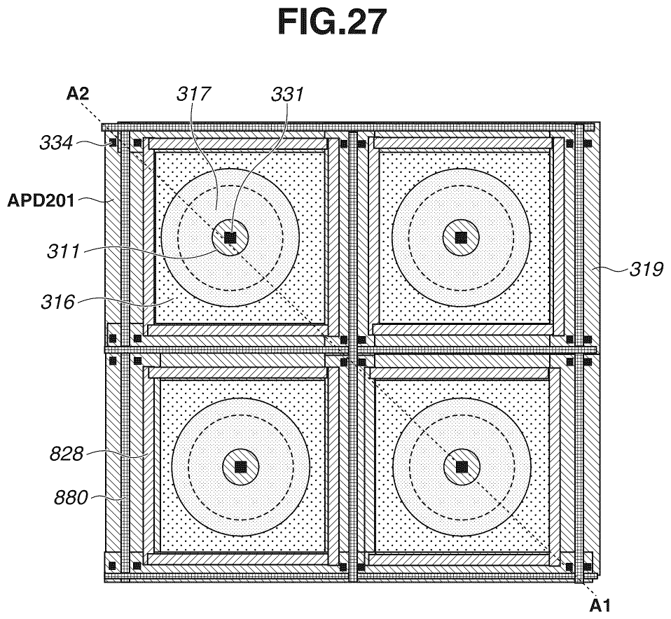

FIG. 27 is a plan view of the APD illustrated in FIG. 26 that is viewed from the second surface F2. FIG. 26 is a cross-sectional view taken along an A1-A2 line in FIG. 27. The trench portion 828 is arranged so as to surround the semiconductor region 316 in a planar view. The trench portion 880 is provided so as to surround the trench portion 828. This configuration can improve the sensitivity of the APD by the reflection of incident light by the trench portion 880 and the trench portion 828. In addition, it is possible to reduce crosstalk between a plurality of APDs.

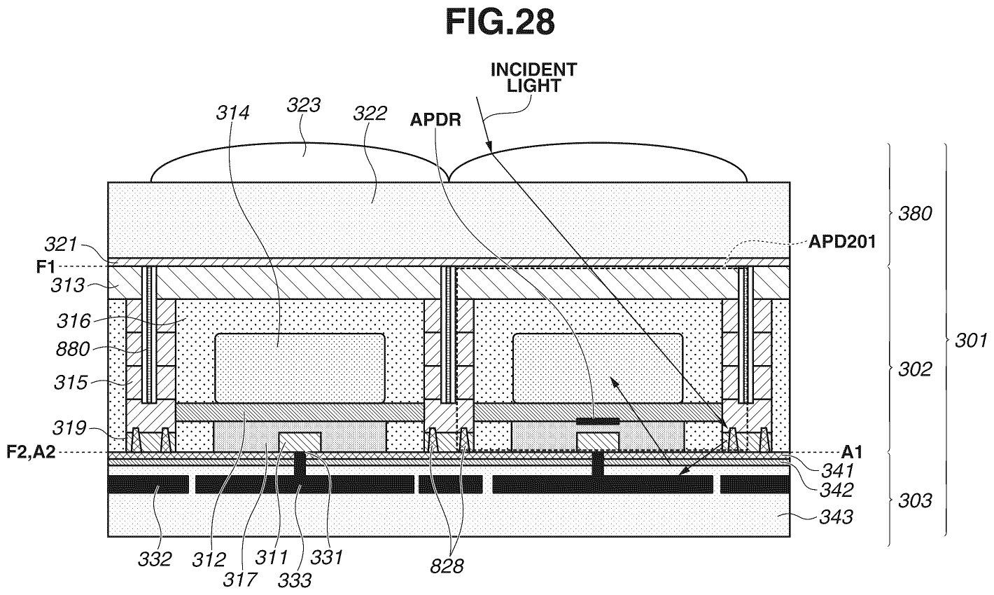

In the present exemplary embodiment, the trench portion 880 penetrates through the semiconductor layer 302, but the trench portion 880 can extend from the first surface F1 up to a halfway depth in the semiconductor layer 302 as illustrated in FIG. 28. This configuration is a configuration in which an end portion of the trench portion 880 on the second surface F2 side is in contact with a semiconductor region provided inside the semiconductor layer 302. With this configuration, it is possible to make an interval between neighboring two trench portions 828 narrower than that in the configuration illustrated in FIG. 26, thereby making it possible to miniaturize the pixels more easily.

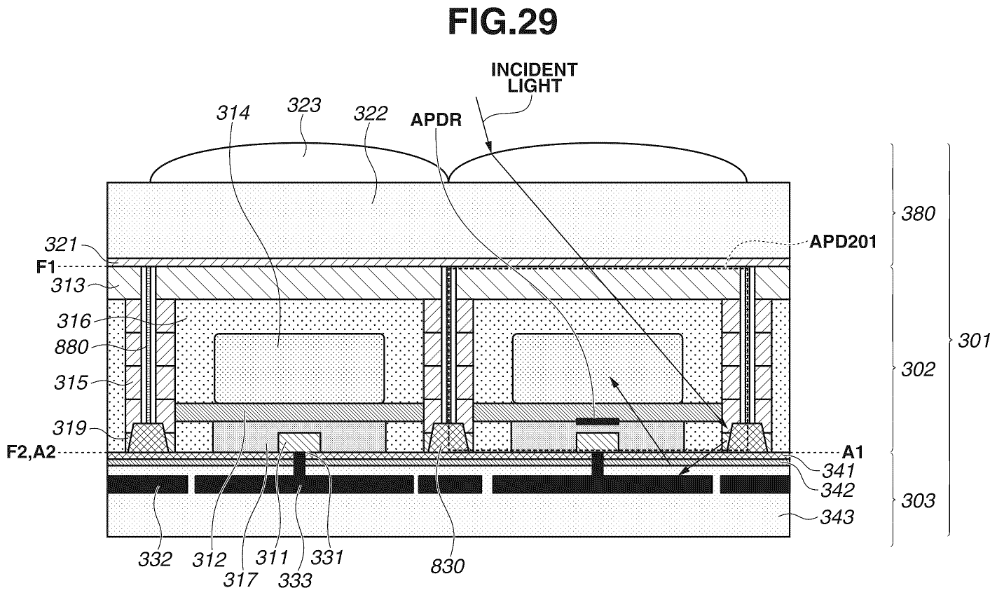

As illustrated in FIG. 29, a configuration can also be employed in which a trench portion 830 extending from the second surface F2 and the trench portion 880 contact inside the semiconductor layer 302. In a case where this configuration is employed, it is possible to make the width of the trench portion 830 wider than the width of the trench portion 880. This configuration makes it possible to perform the reflection of incident light by the trench portion 830 more easily. Metal can also be buried in the trench portion 830. In this case, as compared with the case where the inside of the trench portion 830 is filled with at least one of a silicon compound and air, it is possible to further intensify the reflection of incident light. By forming the trench portion 830 into a taper shape, it is also possible to further intensify the reflection of incident light.

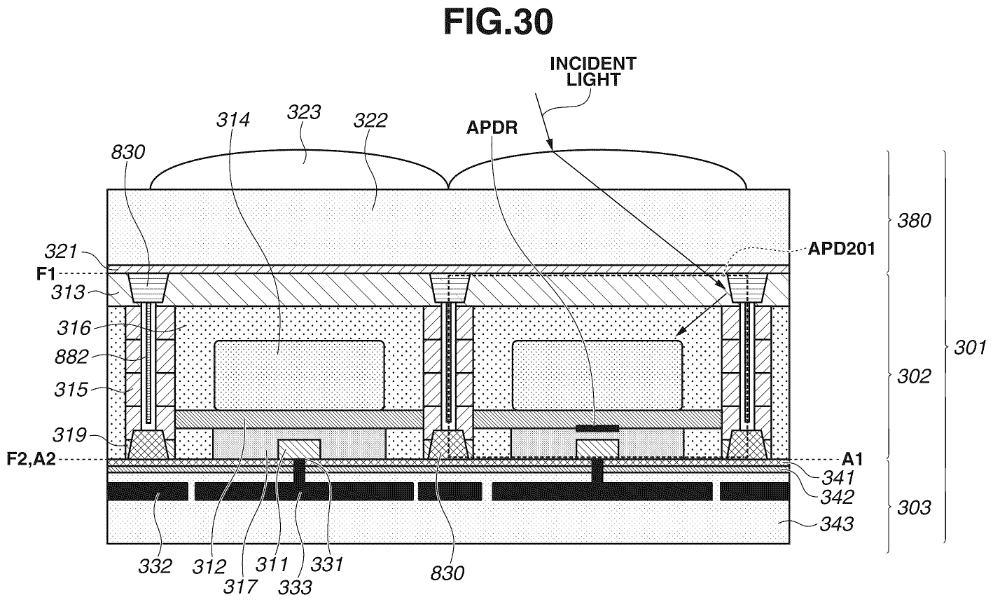

As illustrated in FIG. 30, a trench portion 882 extending from the first surface F1 can include a portion having a taper shape. In this configuration, the trench portion 882 is first formed such that the portion with the taper shape functions as the STI structure. Thereafter, a DTI structure is formed from the bottom surface of the STI structure toward the inside of the semiconductor layer 302. With this configuration, the STI structures can be respectively provided on the first surface F1 and the second surface F2 with the trench portion 882 and the trench portion 830. The inside of each STI structure can be filled with at least one of a silicon compound and air, or can be filled with metal. This structure makes it possible to guide incident light to the inside of the APD more desirably, and improve sensitivity.

### Ninth Exemplary Embodiment

The present exemplary embodiment will be described centering on a difference from the first exemplary embodiment.

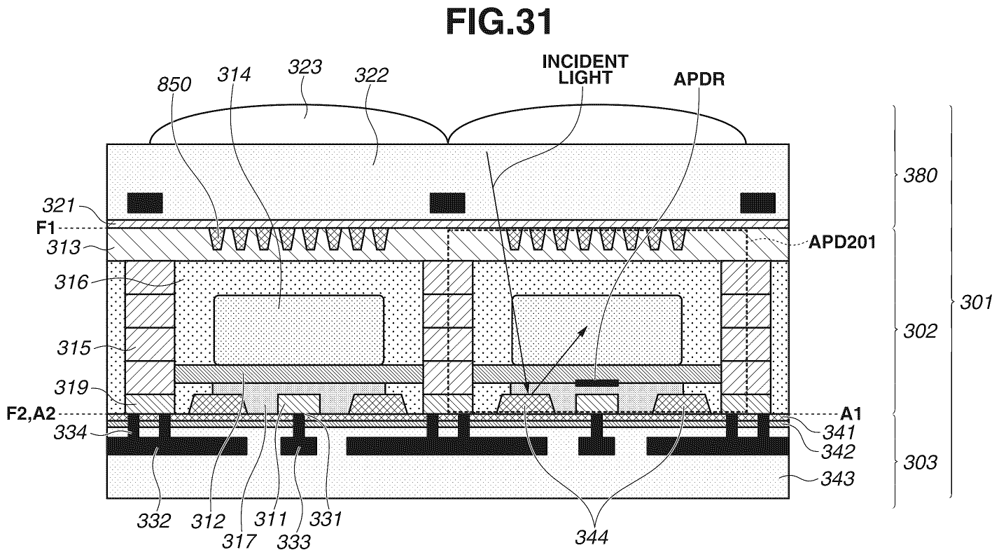

FIG. 31 is a cross-sectional view of an APD according to the present exemplary embodiment. In the present exemplary embodiment, a diffraction structure 850 (formed of a dielectric member) is provided on the first surface F1 serving as an incidence plane of the APD. The diffraction structure 850 can be formed as the STI structure or can be formed as the DTI structure.

This diffraction structure 850 makes it possible to make the length of an optical path of incident light from the entrance to the APD up to photoelectric conversion longer. This configuration makes it possible to improve the sensitivity to light in a long-wavelength band (in particular, near infrared rays).

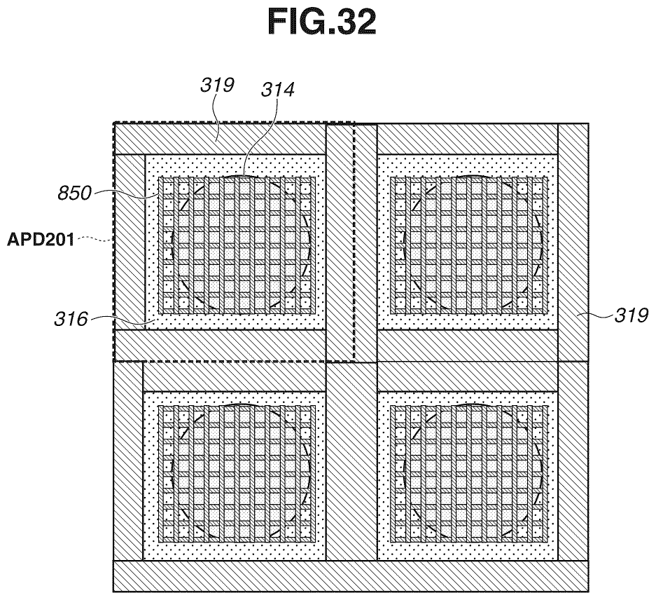

FIG. 32 is a plan view of the APD according to the present exemplary embodiment with respect to the first surface F1. The diffraction structure 850 is provided on the first surface F1 in a lattice pattern. The lattice-shaped diffraction structure 850 is arranged to overlap the semiconductor region 314 in a planar view.

In this manner, the APD according to the present exemplary embodiment provides dielectric members respectively on the first surface F1 and the second surface F2. With this configuration, sensitivity to near infrared rays can be improved.

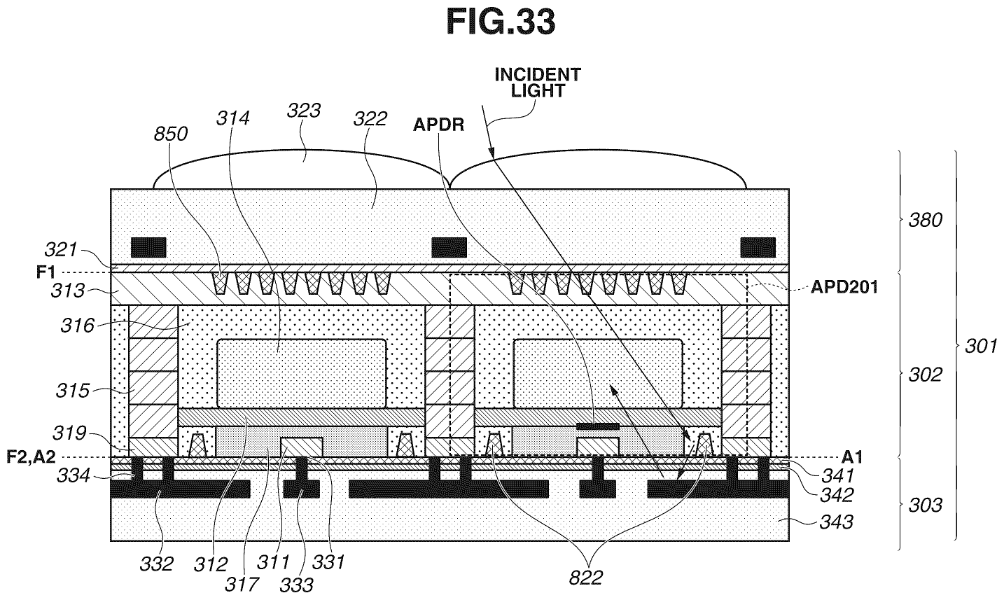

The present exemplary embodiment can be applied in combination with another exemplary embodiment. For example, as illustrated in FIG. 33, a structure combined with the structure of the seventh exemplary embodiment can be employed. Aside from this, a structure combined with the structures of the second to sixth exemplary embodiments and the eighth exemplary embodiment can also be employed.

In the case of these exemplary embodiments, an interval between dielectric members provided on the first surface F1 becomes an interval narrower than an interval between dielectric members provided on the second surface F2. With this configuration, the diffraction structure 850 can diffract incident light more desirably.

### Tenth Exemplary Embodiment

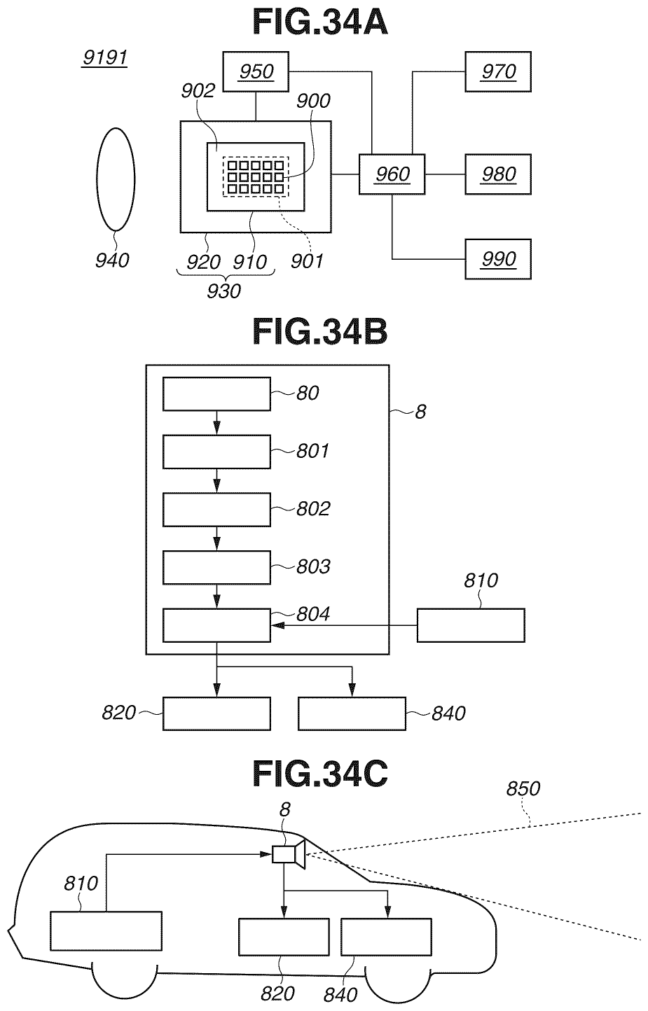

The present exemplary embodiment can be applied to any of the above-described exemplary embodiments. FIG. 34A is a schematic diagram illustrating a device 9191 including a semiconductor apparatus 930 according to the present exemplary embodiment. The photoelectric conversion apparatus (imaging apparatus) according to each of the above-described exemplary embodiments can be used for the semiconductor apparatus 930. The device 9191 including the semiconductor apparatus 930 will now be described in detail. Aside from the semiconductor device 910 including a semiconductor layer 10, the semiconductor apparatus 930 can include a package 920 accommodating the semiconductor device 910, as described above. The package 920 can include a base member on which the semiconductor device 910 is fixed, and a lid member such as glass facing the semiconductor device 910. The package 920 can further include a bonding member such as a bonding wire or a bump for connecting a terminal provided in the base member and a terminal provided in the semiconductor device 910.

The device 9191 can include at least any of an optical device 940, a control device 950, a processing device 960, a display device 970, a storage device 980, and a mechanical device 990. The optical device 940 corresponds to the semiconductor apparatus 930. The optical device 940 is a lens, a shutter, or a mirror, for example. The control device 950 controls the semiconductor apparatus 930. The control device 950 is a semiconductor apparatus such as an application specific integrated circuit (ASIC), for example.

The processing device 960 processes a signal output from the semiconductor apparatus 930. The processing device 960 is a semiconductor apparatus such as a CPU or an ASIC for forming an analog front end (AFE) or a digital front end (DFE). The display device 970 is an electroluminescent (EL) display device or a liquid crystal display device that displays information (image) obtained in the semiconductor apparatus 930. The storage device 980 is a magnetic device or a semiconductor device that stores information (image) obtained in the semiconductor apparatus 930. The storage device 980 is a volatile memory such as a static random access memory (SRAM) or a dynamic random access memory (DRAM), or a nonvolatile memory such as a flash memory or a hard disk drive.

The mechanical device 990 includes a moving unit or a propulsion unit such as a motor or an engine. The device 9191 displays a signal output from the semiconductor apparatus 930 on the display device 970, and transmits to the outside with a communication device (not illustrated) included in the device 9191. For this reason, the device 9191 desirably further includes the storage device 980 and the processing device 960 aside from a storage circuit and a calculation circuit included in the semiconductor apparatus 930. The mechanical device 990 can also be controlled based on a signal output from the semiconductor apparatus 930.

The device 9191 is suitable for an electronic device such as an information terminal having an image capturing function (e.g., smartphone or wearable terminal) or a camera (e.g., interchangeable lens camera, compact camera, video camera, monitoring camera). The mechanical device 990 in a camera can drive the component of the optical device 940 for zooming, focusing, or a shutter operation. Alternatively, the mechanical device 990 in a camera can move the semiconductor apparatus 930 for an image stabilization operation.

The device 9191 can be a transport device such as a vehicle, a ship, or a flight vehicle. The mechanical device 990 in a transport device can be used as a moving device. The device 9191 serving as a transport device is suitable for equipment that transports the semiconductor apparatus 930, or equipment that aids and/or automates driving (steering) using an image capturing function. The processing device 960 for aiding and/or automating driving (steering) can perform processing for operating the mechanical device 990 serving as a moving device, based on information obtained in the semiconductor apparatus 930. Alternatively, the device 9191 can be a medical device such as an endoscope, a measuring device such as a distance measuring sensor, an analytical device such as an electronic microscope, an office device such as a copier, or an industrial device such as a robot.

According to the above-described exemplary embodiment, it becomes possible to obtain good pixel characteristics. It is thus possible to enhance the value of the semiconductor apparatus. The enhancement of the value in here corresponds to at least any of the addition of a function, performance improvement, characteristic improvement, reliability improvement, manufacturing yield ratio improvement, environmental burden reduction, cost reduction, downsizing, and weight saving.

If the semiconductor apparatus 930 according to the present exemplary embodiment is used in the device 9191, the value of the device 9191 can also be enhanced, accordingly. For example, it is possible to obtain superior performance when performing the image capturing of the outside of the transport device or the measuring of an external environment, by mounting the semiconductor apparatus 930 on a transport device. Thus, determining to mount the semiconductor apparatus according to the present exemplary embodiment on a transport device when manufacturing and selling the transport device is advantageous in improving the performance of the transport device itself. The semiconductor apparatus 930 is suitable especially for a transport device that performs drive assist and/or automatic operation of the transport device using information obtained in the semiconductor apparatus.

A photoelectric conversion system and a movable body according to the present exemplary embodiment will now be described with reference to FIGS. 34A to 34C.

FIG. 34A illustrates an example of a photoelectric conversion system related to an in-vehicle camera. A photoelectric conversion system 8 includes a photoelectric conversion apparatus 80. The photoelectric conversion apparatus 80 is the photoelectric conversion apparatus (imaging apparatus) according to any of the above-described exemplary embodiments. The photoelectric conversion system 8 includes an image processing unit 801 that performs image processing on a plurality of pieces of image data acquired by the photoelectric conversion apparatus 80, and a parallax acquisition unit 802 that calculates a parallax (phase difference between parallax images) from the plurality of pieces of image data acquired by the photoelectric conversion system 8. The photoelectric conversion system 8 also includes a distance acquisition unit 803 that calculates a distance to a target object based on the calculated parallax, and a collision determination unit 804 that determines whether collision is likely to occur, based on the calculated distance. In this example, the parallax acquisition unit 802 and the distance acquisition unit 803 serve as an example of a distance information acquisition unit that acquires distance information regarding a distance to a target object. More specifically, the distance information is information regarding a parallax, a defocus amount, and a distance to a target object. The collision determination unit 804 can determine collision likelihood using any of these pieces of distance information. The distance information acquisition unit can be implemented by dedicatedly-designed hardware, or can be implemented by a software module. Alternatively, the distance information acquisition unit can be implemented by a field programmable gate array (FPGA) or an application specific integrated circuit (ASIC), or can be implemented by the combination of these.

The photoelectric conversion system 8 is connected with a vehicle information acquisition apparatus 810, and can acquire vehicle information such as a vehicle speed, a yaw rate, or a rudder angle. In addition, an electronic control unit (ECU) 820 (control unit) is connected to the photoelectric conversion system 8. The ECU 820 serves as a control apparatus that outputs a control signal for generating braking force, to a vehicle based on a determination result obtained by the collision determination unit 804. The photoelectric conversion system 8 is also connected with an alarm apparatus 840 that raises an alarm to a driver based on a determination result obtained by the collision determination unit 804. For example, in a case where the determination result obtained by the collision determination unit 804 indicates high collision likelihood, the ECU 820 performs vehicle control for avoiding collision or reducing damages by braking, releasing an accelerator, or suppressing engine output. The alarm apparatus 840 issues an alarm to a user by sounding an alarm, displaying warning information on a screen of a car navigation system, or vibrating a seatbelt or a steering wheel.

In the present exemplary embodiment, the photoelectric conversion system 8 captures an image of the periphery of the vehicle such as the front side or the rear side, for example. FIG. 34C illustrates the photoelectric conversion system 8 for capturing an image of a vehicle front side (imaging range 850). The vehicle information acquisition apparatus 810 issues an instruction to the photoelectric conversion system 8 or the photoelectric conversion apparatus 80. With this configuration, the accuracy of distance measurement can be enhanced.

The above description has been given of an example in which control is performed not to collide with another vehicle. The photoelectric conversion system can also be applied to the control for performing automatic operation by following another vehicle, or the control for performing automatic operation not to deviate from a lane. Furthermore, the photoelectric conversion system 8 can be applied to a movable body (moving apparatus) such as a vessel, an aircraft, or an industrial robot, for example, aside from a vehicle such as an automobile. Moreover, the photoelectric conversion system can be applied to equipment that extensively uses object recognition, such as an intelligent transport system (ITS), in addition to a movable body.

### Eleventh Exemplary Embodiment

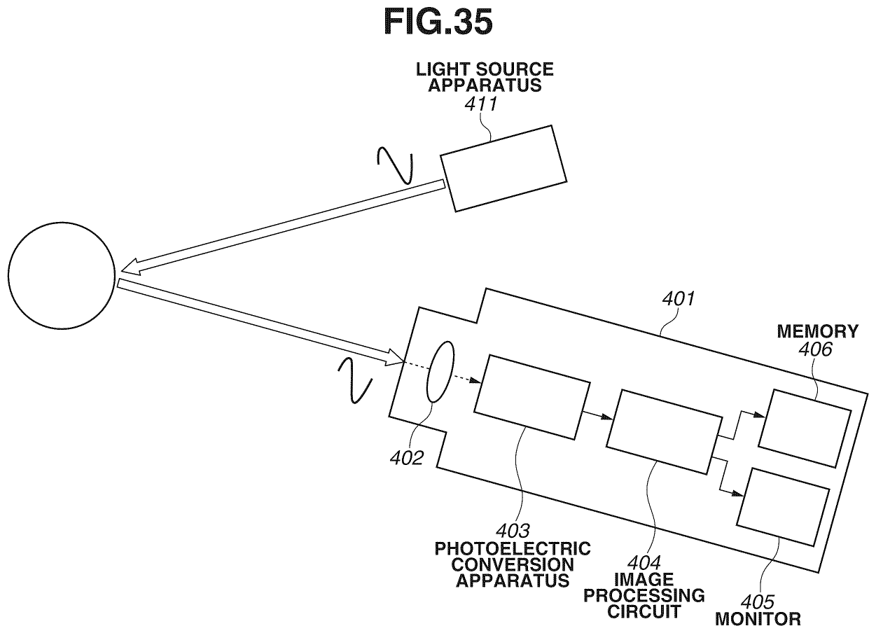

A photoelectric conversion system serving as an example of equipment according to the present exemplary embodiment will now be described with reference to FIG. 35. FIG. 35 is a block diagram illustrating a configuration example of a distance image sensor serving as a photoelectric conversion system according to the present exemplary embodiment.

As illustrated in FIG. 35, a distance image sensor 401 includes an optical system 402, a photoelectric conversion apparatus 403, an image processing circuit 404, a monitor 405, and a memory 406. The photoelectric conversion apparatus according to any of the above-described exemplary embodiments can be applied to the photoelectric conversion apparatus 403. In addition, the distance image sensor 401 can acquire a distance image corresponding to a distance to a subject by receiving light (modulated light or pulse light) that has been projected from a light source apparatus 411 toward the subject, and reflected on the front surface of the subject.

The optical system 402 includes one or more lenses, guides image light (incident light) from the subject to the photoelectric conversion apparatus 403, and forms an image on a light receiving surface (sensor portion) of the photoelectric conversion apparatus 403.

The photoelectric conversion apparatus described in the above-described embodiment is applied to the photoelectric conversion apparatus 403, and a distance signal indicating a distance obtained from a light receiving signal output from the photoelectric conversion apparatus 403 is supplied to the image processing circuit 404.

The image processing circuit 404 performs image processing of constructing a distance image, based on the distance signal supplied from the photoelectric conversion apparatus 403. A distance image (image data) obtained by the image processing is then supplied to the monitor 405 and displayed thereon, or supplied to the memory 406 and stored (recorded) therein.

By applying the above-described photoelectric conversion apparatus, the distance image sensor 401 having the above-described configuration can acquire a more accurate distance image in accordance with characteristic enhancement of a pixel, for example.

### Modified Exemplary Embodiment

The present disclosure is not limited to the above-described exemplary embodiments, and various modifications can be made.

For example, an example in which a partial configuration of a certain exemplary embodiment is added to another exemplary embodiment, and an example in which a partial configuration of a certain exemplary embodiment is replaced with a partial configuration of another exemplary embodiment are also included in the exemplary embodiments of the present disclosure.

The devices described in the above-described seventh and eighth exemplary embodiments are examples of the photoelectric conversion systems to which the photoelectric conversion apparatus can be applied, and the device and the photoelectric conversion system to which the photoelectric conversion apparatus of the present invention can be applied is not limited to the configuration illustrated in FIGS. 34A to 34C and 35.

The above-described exemplary embodiments merely indicate examples of substantiation in executing the present invention, and the technical scope of the prevent invention is not to be construed in a limited manner based on these embodiments. That is, the present invention can be executed in various forms without departing from the technical idea or major features thereof.

The exemplary embodiments described above can be appropriately changed without departing from the technical idea. The disclosure in this specification is not limited to matters described in this specification, and includes all matters that can be identified from this specification and the drawings accompanying this specification. The disclosure in this specification includes a complementary set of individual concepts described in this specification. More specifically, if “A is larger than B” is described in this specification, even if the description “B is not larger than A” is omitted, this specification is assumed to disclose that “B is not larger than A”. This is because, in a case where “A is larger than B” is described, a case where “B is not larger than A” is assumed to be considered.

The present disclosure includes the following configurations.

### (Configuration 1)

A photoelectric conversion apparatus including:
an avalanche photodiode configured to perform an avalanche multiplication operation with a first voltage and a second voltage that are applied; and
a semiconductor layer having a first surface on which light is incident, and a second surface facing the first surface,
in which the avalanche photodiode includes
a first semiconductor region of a first conductivity type that is provided at a first depth from the first surface in the semiconductor layer,
a second semiconductor region of a second conductivity type that exists at a position closer to the second surface than the first semiconductor region,
a third semiconductor region of the first conductivity type that exists at a position closer to the second surface than the second semiconductor region, is applied with the first voltage, and is provided at a predetermined depth position of the semiconductor layer,
a region to which the second voltage is applied,
a fourth semiconductor region of the first conductivity type that is provided between the region and the third semiconductor region, and
a dielectric member that is positioned in a portion overlapping at least the fourth semiconductor region in a planar view with respect to the second surface, and includes a portion extending from at least the second surface to an inside of the semiconductor layer, and
in which the portion is provided at the predetermined depth position.

### (Configuration 2)

The photoelectric conversion apparatus according to Configuration 1,
in which a fifth semiconductor region of the first conductivity type is provided between the third semiconductor region and the fourth semiconductor region, and
in which the dielectric member extends from the portion overlapping the fourth semiconductor region, to a portion overlapping the fifth semiconductor region in the planar view.

### (Configuration 3)

The photoelectric conversion apparatus according to Configuration 1 or 2, in which the dielectric member is arranged at a position overlapping the first semiconductor region in the planar view.

### (Configuration 4)

The photoelectric conversion apparatus according to any one of Configurations 1 to 3, in which the dielectric member is arranged at a position overlapping the second semiconductor region in the planar view.

### (Configuration 5)

The photoelectric conversion apparatus according to any one of Configurations 1 to 4, in which the dielectric member extends in a depth direction up to a position shallower than the second semiconductor region in a depth from the second surface.

### (Configuration 6)

The photoelectric conversion apparatus according to any one of Configurations 1 to 5, in which the dielectric member is provided in a ring shape to surround the third semiconductor region in the planar view.

### (Configuration 7)

The photoelectric conversion apparatus according to any one of Configurations 1 to 6, in which the third semiconductor region is connected with a contact plug, and is applied with the first voltage via the contact plug.

### (Configuration 8)

The photoelectric conversion apparatus according to any one of Configurations 1 to 7,
in which the region includes a contact plug applied with the second voltage, and a wire connected to the contact plug, and
in which the dielectric member includes a portion overlapping the wire in the planar view.

### (Configuration 9)

The photoelectric conversion apparatus according to Configuration 7,
in which the region includes a contact plug applied with the second voltage, and a wire connected to the contact plug, and
in which, in the planar view, the dielectric member includes a portion overlapping the wire, and
in which, in the planar view, the wire includes a portion overlapping the dielectric member and the fifth semiconductor region.

### (Configuration 10)

A photoelectric conversion apparatus including:
a plurality of avalanche photodiodes each performing an avalanche multiplication operation with a first voltage and a second voltage that are applied; and
a semiconductor layer having a first surface on which light is incident, and a second surface facing the first surface,
in which each of the plurality of avalanche photodiodes includes
a first semiconductor region of a first conductivity type that is provided at a first depth from the first surface in the semiconductor layer,
a second semiconductor region of a second conductivity type that exists at a position closer to the second surface than the first semiconductor region,
a third semiconductor region of the first conductivity type that exists at a position closer to the second surface than the second semiconductor region, and is provided at a predetermined depth position of the semiconductor layer, to which the first voltage is applied,
a region to which the second voltage is applied, and
a dielectric member,
in which an isolation region for isolating the plurality of avalanche diodes is provided, and
in which the dielectric member is positioned between the isolation region and the third semiconductor region in a planar view with respect to the second surface, and includes a portion extending from at least the second surface over the predetermined depth position.

### (Configuration 11)

The photoelectric conversion apparatus according to any one of Configurations 1 to 10, in which the region is a semiconductor region of the second conductivity type.

### (Configuration 12)

The photoelectric conversion apparatus according to any one of Configurations 1 to 10, in which the region is a metal member embedded in the semiconductor layer.

### (Configuration 13)

The photoelectric conversion apparatus according to any one of Configurations 1 to 12, in which the first voltage is a positive voltage and the second voltage is a negative voltage.

### (Configuration 14)

The photoelectric conversion apparatus according to Configuration 13, in which the first conductivity type is an N type and the second conductivity type is a P type.

### (Configuration 15)

The photoelectric conversion apparatus according to any one of Configurations 1 to 14, in which the first surface has a diffraction structure for diffracting incident light.

### (Configuration 16)

The photoelectric conversion apparatus according to Configuration 15,
in which a plurality of the dielectric members each including the portion is included,
in which the diffraction structure includes a plurality of dielectric members, and
in which an interval between one dielectric member and a different dielectric member of the plurality of dielectric members included in the diffraction structure is narrower than an interval between one dielectric member and a different dielectric member of the plurality of dielectric members each including the portion.

### (Configuration 17)

The photoelectric conversion apparatus according to any one of Configurations 1 to 16,
in which a trench portion extending from the first surface toward the second surface is included, and
in which the trench portion is arranged to surround the dielectric member in a planar view with respect to the second surface.

### (Configuration 18)

The photoelectric conversion apparatus according to Configuration 17, in which the trench portion penetrates through the semiconductor layer.

### (Configuration 19)

The photoelectric conversion apparatus according to Configuration 17 or 18, in which an end portion of the trench portion that is closest to the second surface is in contact with a semiconductor region provided inside the semiconductor layer.

### (Configuration 20)

The photoelectric conversion apparatus according to any one of Configurations 1 to 19,
in which a plurality of avalanche photodiodes each being the avalanche photodiode,
in which a sixth semiconductor region of the second conductivity type is arranged between one avalanche photodiode and a different avalanche photodiode of the plurality of avalanche photodiodes, and
in which the dielectric member is provided inside the sixth semiconductor region.

### (Configuration 21)

The photoelectric conversion apparatus according to Configuration 20,
in which a trench portion extending from the first surface toward the second surface is included,
in which the trench portion is arranged to surround the dielectric member in a planar view with respect to the second surface, and
in which the trench portion is provided inside the sixth semiconductor region.

### (Configuration 22)

The photoelectric conversion apparatus according to Configuration 21, in which the trench portion and the dielectric member are connected.

### (Configuration 23)

The photoelectric conversion apparatus according to any one of Configurations 1 to 22,
in which the photoelectric conversion apparatus is a structure in which a plurality of substrates is stacked, one substrate of the plurality of substrates includes a wiring layer and the semiconductor layer, and the second surface is positioned between the first surface and the wiring layer, and
in which a different substrate of the plurality of substrates and the one substrate are stacked.

### (Configuration 24)

A photoelectric conversion system including:
the photoelectric conversion apparatus according to any one of Configurations 1 to 23; and
a signal processing unit configured to generate an image using a signal output from the photoelectric conversion apparatus.

### (Configuration 25)

A moving body including:
the photoelectric conversion apparatus according to any one of Configurations 1 to 23; and
a control unit configured to control a movement of the moving body using a signal output from the photoelectric conversion apparatus.

### (Configuration 26)

Equipment including:
the photoelectric conversion apparatus according to any one of Configurations 1 to 23,
in which the device further includes at least any of the following:
an optical device adapted to the photoelectric conversion apparatus;
a control device configured to control the photoelectric conversion apparatus;
a processing device configured to process a signal output from the photoelectric conversion apparatus;
a display device configured to display information obtained by the photoelectric conversion apparatus;
a storage device configured to store information obtained by the photoelectric conversion apparatus, and
a mechanical device configured to operate based on information obtained by the photoelectric conversion apparatus.

The present invention is not limited to the above-described exemplary embodiments, and various changes and modifications can be made without departing from the spirit and the scope of the present invention. Accordingly, the following claims are appended to publicize the scope of the present invention.

The technique of the present disclosure can implement improvement in photoelectric conversion efficiency of an avalanche photodiode.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A photoelectric conversion apparatus comprising:
an avalanche photodiode configured to perform an avalanche multiplication operation with a first voltage and a second voltage that are applied; and
a semiconductor layer having a first surface on which light is incident, and a second surface facing the first surface,
wherein the avalanche photodiode includes
a first semiconductor region of a first conductivity type that is provided at a first depth from the first surface in the semiconductor layer,
a second semiconductor region of a second conductivity type that exists at a position closer to the second surface than the first semiconductor region,
a third semiconductor region of the first conductivity type that exists at a position closer to the second surface than the second semiconductor region, is applied with the first voltage, and is provided at a predetermined depth position of the semiconductor layer,
a region to which the second voltage is applied,
a fourth semiconductor region of the first conductivity type that is provided between the region and the third semiconductor region, and
a dielectric member that is positioned in a portion overlapping at least the fourth semiconductor region in a planar view with respect to the second surface, and
includes a portion extending from at least the second surface to an inside of the semiconductor layer, and
wherein the portion is provided at the predetermined depth position.

2. The photoelectric conversion apparatus according to claim 1,
wherein a fifth semiconductor region of the first conductivity type is provided between the third semiconductor region and the fourth semiconductor region, and
wherein the dielectric member extends from the portion overlapping the fourth semiconductor region to a portion overlapping the fifth semiconductor region in the planar view.

3. The photoelectric conversion apparatus according to claim 1, wherein the dielectric member is arranged at a position overlapping the first semiconductor region in the planar view.

4. The photoelectric conversion apparatus according to claim 2, wherein the dielectric member is arranged at a position overlapping the first semiconductor region in the planar view.

5. The photoelectric conversion apparatus according to claim 1, wherein the dielectric member is arranged at a position overlapping the second semiconductor region in the planar view.

6. The photoelectric conversion apparatus according to claim 2, wherein the dielectric member is arranged at a position overlapping the second semiconductor region in the planar view.

7. The photoelectric conversion apparatus according to claim 3, wherein the dielectric member is arranged at a position overlapping the second semiconductor region in the planar view.

8. The photoelectric conversion apparatus according to claim 4, wherein the dielectric member is arranged at a position overlapping the second semiconductor region in the planar view.

9. The photoelectric conversion apparatus according to claim 1, wherein the dielectric member extends in a depth direction up to a position shallower than the second semiconductor region in a depth from the second surface.

10. The photoelectric conversion apparatus according to claim 2, wherein the dielectric member extends in a depth direction up to a position shallower than the second semiconductor region in a depth from the second surface.

11. The photoelectric conversion apparatus according to claim 8, wherein the dielectric member extends in a depth direction up to a position shallower than the second semiconductor region in a depth from the second surface.

12. The photoelectric conversion apparatus according to claim 1, wherein the dielectric member is provided in a ring shape to surround the third semiconductor region in the planar view.

13. The photoelectric conversion apparatus according to claim 8, wherein the dielectric member is provided in a ring shape to surround the third semiconductor region in the planar view.

14. The photoelectric conversion apparatus according to claim 11, wherein the dielectric member is provided in a ring shape to surround the third semiconductor region in the planar view.

15. The photoelectric conversion apparatus according to claim 1, wherein the third semiconductor region is connected with a contact plug, and is applied with the first voltage via the contact plug.

16. The photoelectric conversion apparatus according to claim 14, wherein the third semiconductor region is connected with a contact plug and is applied with the first voltage via the contact plug.

17. The photoelectric conversion apparatus according to claim 1,
wherein the region includes a contact plug applied with the second voltage, and a wire connected to the contact plug, and
wherein the dielectric member includes a portion overlapping the wire in the planar view.

18. The photoelectric conversion apparatus according to claim 2,
wherein the region includes a contact plug applied with the second voltage, and a wire connected to the contact plug, and
wherein, in the planar view, the wire includes a portion overlapping the dielectric member and the fifth semiconductor region.

19. The photoelectric conversion apparatus according to claim 16,
wherein the region includes a contact plug applied with the second voltage, and a wire connected to the contact plug, and
wherein, in the planar view, the wire includes a portion overlapping the dielectric member and the fifth semiconductor region.

20. A photoelectric conversion apparatus comprising:
a plurality of avalanche photodiodes each performing an avalanche multiplication operation with a first voltage and a second voltage that are applied; and
a semiconductor layer having a first surface on which light is incident, and a second surface facing the first surface,
wherein each of the plurality of avalanche photodiodes includes
a first semiconductor region of a first conductivity type that is provided at a first depth from the first surface in the semiconductor layer,
a second semiconductor region of a second conductivity type that exists at a position closer to the second surface than the first semiconductor region,
a third semiconductor region of the first conductivity type that exists at a position closer to the second surface than the second semiconductor region, and is provided at a predetermined depth position of the semiconductor layer, to which the first voltage is applied,
a region to which the second voltage is applied, and
a dielectric member,
wherein an isolation region for isolating the plurality of avalanche diodes is provided, and
wherein the dielectric member is positioned between the isolation region and the third semiconductor region in a planar view with respect to the second surface, and includes a portion extending from at least the second surface over the predetermined depth position.

21. The photoelectric conversion apparatus according to claim 1, wherein the region is a semiconductor region of the second conductivity type.

22. The photoelectric conversion apparatus according to claim 19, wherein the region is a semiconductor region of the second conductivity type.

23. The photoelectric conversion apparatus according to claim 20, wherein the region is a semiconductor region of the second conductivity type.

24. The photoelectric conversion apparatus according to claim 1, wherein the region is a metal member embedded in the semiconductor layer.

25. The photoelectric conversion apparatus according to claim 20, wherein the region is a metal member embedded in the semiconductor layer.

26. The photoelectric conversion apparatus according to claim 1, wherein the first voltage is a positive voltage and the second voltage is a negative voltage.

27. The photoelectric conversion apparatus according to claim 20, wherein the first voltage is a positive voltage and the second voltage is a negative voltage.

28. The photoelectric conversion apparatus according to claim 26, wherein the first conductivity type is an N type and the second conductivity type is a P type.

29. The photoelectric conversion apparatus according to claim 27, wherein the first conductivity type is an N type and the second conductivity type is a P type.

30. The photoelectric conversion apparatus according to claim 1, wherein the first surface has a diffraction structure for diffracting incident light.

31. The photoelectric conversion apparatus according to claim 20, wherein the first surface has a diffraction structure for diffracting incident light.

32. The photoelectric conversion apparatus according to claim 30,
wherein a plurality of the dielectric members each including the portion is included,
wherein the diffraction structure includes a plurality of dielectric members, and
wherein an interval between one dielectric member and a different dielectric member of the plurality of dielectric members included in the diffraction structure is narrower than an interval between one dielectric member and a different dielectric member of the plurality of dielectric members each including the portion.

33. The photoelectric conversion apparatus according to claim 31,
wherein a plurality of the dielectric members each including the portion is included,
wherein the diffraction structure includes a plurality of dielectric members, and
wherein an interval between one dielectric member and a different dielectric member of the plurality of dielectric members included in the diffraction structure is narrower than an interval between one dielectric member and a different dielectric member of the plurality of dielectric members each including the portion.

34. The photoelectric conversion apparatus according to claim 1,
wherein a trench portion extending from the first surface toward the second surface is included, and
wherein the trench portion is arranged to surround the dielectric member in a planar view with respect to the second surface.

35. The photoelectric conversion apparatus according to claim 20,
wherein a trench portion extending from the first surface toward the second surface is included, and
wherein the trench portion is arranged to surround the dielectric member in a planar view with respect to the second surface.

36. The photoelectric conversion apparatus according to claim 34, wherein the trench portion penetrates through the semiconductor layer.

37. The photoelectric conversion apparatus according to claim 35, wherein the trench portion penetrates through the semiconductor layer.

38. The photoelectric conversion apparatus according to claim 34, wherein an end portion of the trench portion that is closest to the second surface is in contact with a semiconductor region provided inside the semiconductor layer.

39. The photoelectric conversion apparatus according to claim 1,
wherein a plurality of avalanche photodiodes each being the avalanche photodiode,
wherein a sixth semiconductor region of the second conductivity type is arranged between one avalanche photodiode and a different avalanche photodiode of the plurality of avalanche photodiodes, and
wherein the dielectric member is provided inside the sixth semiconductor region.

40. The photoelectric conversion apparatus according to claim 20,
wherein a plurality of avalanche photodiodes each being the avalanche photodiode,
wherein a sixth semiconductor region of the second conductivity type is arranged between one avalanche photodiode and a different avalanche photodiode of the plurality of avalanche photodiodes, and
wherein the dielectric member is provided inside the sixth semiconductor region.

41. The photoelectric conversion apparatus according to claim 39,
wherein a trench portion extending from the first surface toward the second surface is included, and
wherein the trench portion is arranged to surround the dielectric member in a planar view with respect to the second surface, and
wherein the trench portion is provided inside the sixth semiconductor region.

42. The photoelectric conversion apparatus according to claim 41, wherein the trench portion and the dielectric member are connected.

43. The photoelectric conversion apparatus according to claim 1,
wherein the photoelectric conversion apparatus is a structure in which a plurality of substrates is stacked, one substrate of the plurality of substrates includes a wiring layer and the semiconductor layer, and the second surface is positioned between the first surface and the wiring layer, and
wherein a different substrate of the plurality of substrates and the one substrate are stacked.

44. The photoelectric conversion apparatus according to claim 20,
wherein the photoelectric conversion apparatus is a structure in which a plurality of substrates is stacked, one substrate of the plurality of substrates includes a wiring layer and the semiconductor layer, and the second surface is positioned between the first surface and the wiring layer, and
wherein a different substrate of the plurality of substrates and the one substrate are stacked.

45. The photoelectric conversion apparatus according to claim 21, wherein the region, the dielectric member, and the third semiconductor region are arranged at a same depth.

46. The photoelectric conversion apparatus according to claim 23, wherein the region, the dielectric member, and the third semiconductor region are arranged at a same depth.

47. The photoelectric conversion apparatus according to claim 45, wherein, in the planar view, an entire dielectric member overlaps the second semiconductor region.

48. The photoelectric conversion apparatus according to claim 46, wherein, in the planar view, an entire dielectric member overlaps the second semiconductor region.

49. A photoelectric conversion system comprising:
the photoelectric conversion apparatus according to claim 1; and
a signal processing unit configured to generate an image using a signal output from the photoelectric conversion apparatus.

50. A moving body comprising:
the photoelectric conversion apparatus according to claim 1; and
a control unit configured to control a movement of the moving body using a signal output from the photoelectric conversion apparatus.

51. Equipment comprising:
the photoelectric conversion apparatus according to claim 1, and
at least one device selected from a group consisting of:
an optical device adapted to the photoelectric conversion apparatus;
a control device configured to control the photoelectric conversion apparatus;
a processing device configured to process a signal output from the photoelectric conversion apparatus;
a display device configured to display information obtained by the photoelectric conversion apparatus;
a storage device configured to store information obtained by the photoelectric conversion apparatus, and
a mechanical device configured to operate based on information obtained by the photoelectric conversion apparatus.
